(19) United States
(12) Patent Application Publication
(10) Pub. No.: US 2026/0143930 A1
(43) Pub. Date: May 21, 2026

(54) DISPLAY SUBSTRATE, METHOD FOR PREPARING THE SAME, AND DISPLAY APPARATUS

(71) Applicants: Beijing BOE Technology Development Co., Ltd., Beijing (CN); BOE Technology Group Co., Ltd., Beijing (CN)

(72) Inventors: Bingwei WANG, Beijing (CN); Chunyang WANG, Beijing (CN); Hejin WANG, Beijing (CN)

(21) Appl. No.: 18/697,322

(22) PCT Filed: Jul. 31, 2023
(86) PCT No.: PCT/CN2023/110286

§ 371 Date: Mar. 29, 2024

(51) Int. Cl. H10K 59/131; H10K 59/12; H10K 59/122; H10K 59/80

(52) U.S. Cl. CPC H10K 59/131; H10K 59/1201; H10K 59/122; H10K 59/8723; H10K 59/873

(57) ABSTRACT

A display substrate, a method for preparing the same, and a display apparatus. The display substrate includes pixel island regions, aperture regions, and connecting bridge regions, each pixel island region includes a transition region connected to a connecting bridge region and a pixel region; a base substrate, and a first gate insulating layer, a second gate insulating layer and an interlayer insulating layer that are sequentially stacked in a direction away from the base substrate; orthographic projections of the first gate insulating layer, the second gate insulating layer and the interlayer insulating layer on the base substrate cover the pixel region and extend into the transition region; along a direction of the pixel island region pointing toward the connecting bridge region, the first gate insulating layer, the second gate insulating layer and the interlayer insulating layer have different cutoff positions in the transition region.

### CROSS-REFERENCE TO RELATED APPLICATIONS

This application is a National Stage of International Application No. PCT/CN2023/110286, filed Jul. 31, 2023, which is hereby incorporated by reference in its entireties.

### TECHNICAL FIELD

The present disclosure relates to the field of display technology, in particular to a display substrate, a method for preparing the same, and a display apparatus.

### BACKGROUND

With the development of display technology, organic light emitting diodes (OLEDs), which can be for the flexible display, have contributed to the diversification of displays and have gradually become the mainstream of display technology. In some related arts, OLED flexible display apparatuses are able to meet the bending of two-dimensional surfaces, but they are not applicable to more complex display apparatuses (e.g., wearable devices, etc.) for the flexible requirements of the display substrates.

In order to develop the display function of the OLED flexible display apparatus, in some related arts, an island for preparing a pixel region and a bridge for routing wirings are formed by digging holes in a base substrate material of the OLED flexible display apparatus, and stretching of the display apparatus is realized by the deformation of the bridge.

### SUMMARY

The present disclosure provides a display substrate, a method for preparing the same, and a display apparatus, as follows.

The present disclosure provides a display substrate including: a plurality of pixel island regions, a plurality of aperture regions, and a plurality of connecting bridge regions, wherein each of the pixel island regions includes a transition region connected to a connecting bridge region and a pixel region; and
the display substrate includes: a base substrate, and a first gate insulating layer, a second gate insulating layer and an interlayer insulating layer that are sequentially stacked in a direction away from the base substrate; wherein orthographic projections of the first gate insulating layer, the second gate insulating layer and the interlayer insulating layer on the base substrate each cover the pixel region and extend into the transition region; and along a direction of the pixel island region pointing toward the connecting bridge region, the first gate insulating layer, the second gate insulating layer and the interlayer insulating layer have different cutoff positions in the transition region.

In one possible implementation, in the display substrate provided by embodiments of the present disclosure, the cutoff position of the second gate insulating layer in the transition region is adjacent to the connecting bridge region, and the cutoff position of the first gate insulating layer in the transition region and the cutoff position of the interlayer insulating layer in the transition region are both away from the connecting bridge region.

In one possible implementation, in the display substrate provided by embodiments of the present disclosure, the transition region is divided into a first region, a second region, and a third region along the direction of the pixel island region pointing toward the connecting bridge region, wherein the orthographic projection of the second gate insulating layer on the base substrate covers an orthographic projection of the transition region on the base substrate, and the orthographic projection of the first gate insulating layer on the base substrate covers orthographic projections of the first region and the second region on the base substrate, the orthographic projection of the interlayer insulating layer on the base substrate covers the orthographic projection of the first region on the base substrate.

In one possible implementation, in the display substrate provided by embodiments of the present disclosure, the display substrate further includes: a first flat layer, a second flat layer, and a passivation layer sequentially stacked on one side of the interlayer insulating layer away from the base substrate, wherein orthographic projections of the first flat layer and the second flat layer on the base substrate each cover the pixel island region and the connecting bridge region, and an orthographic projection of the passivation layer on the base substrate at least covers the pixel island region; wherein
the first flat layer and the second flat layer have a first partition groove penetrating through the first flat layer and the second flat layer in the transition region, the passivation layer covers the first partition groove, and the first partition groove above the passivation layer is filled with an organic compensation layer, so that an overall thickness of the transition region coincides with an overall thickness of the pixel region of the pixel island region.

In one possible implementation, in the display substrate provided by embodiments of the present disclosure, the display substrate further includes a pixel definition layer, a spacer, and an organic encapsulation layer sequentially stacked on one side of the passivation layer away from the base substrate, wherein the organic compensation layer is of the same material as one of the pixel definition layer, the spacer, or the organic encapsulation layer.

In one possible implementation, in the display substrate provided by embodiments of the present disclosure, the display substrate further includes: a blocking layer between the base substrate and the first gate insulating layer, a buffer layer between the blocking layer and the first gate insulating layer, a first inorganic encapsulation layer between the spacer and the organic encapsulation layer, and a second inorganic encapsulation layer on one side of the organic encapsulation layer away from the base substrate; and
a first isolation column is provided in a side portion of the transition region close to a aperture region, wherein the first isolation column includes at least a part of film layers among the blocking layer, the buffer layer, the first gate insulating layer, the second gate insulating layer, the passivation layer, the first inorganic encapsulation layer, or the second inorganic encapsulation layer.

In one possible implementation, in the display substrate provided by embodiments of the present disclosure, the first isolation column includes the blocking layer, the buffer layer, the first gate insulating layer, the second gate insulating layer, the passivation layer, the organic compensation layer, the first inorganic encapsulation layer, the organic encapsulation layer, and the second inorganic encapsulation layer.

In one possible implementation, in the display substrate provided by embodiments of the present disclosure, the first isolation column includes the blocking layer, the buffer layer, the first gate insulating layer, the second gate insulating layer, the passivation layer, the first inorganic encapsulation layer, the organic encapsulation layer, and the second inorganic encapsulation layer.

In one possible implementation, in the display substrate provided by embodiments of the present disclosure, a side portion of the first isolation column close to the aperture region is immediately adjacent to the aperture region.

In one possible implementation, in the display substrate provided by embodiments of the present disclosure, a side portion of the first isolation column close to the aperture region is provided with a first preset distance from the aperture region.

In one possible implementation, in the display substrate provided by embodiments of the present disclosure, the first preset distance is in a range of 1 μm to 5 μm.

In one possible implementation, in the display substrate provided by embodiments of the present disclosure, a second isolation column is provided in another side portion of the transition region close to the aperture region, wherein the second isolation column has the same film layer structure as the first isolation column.

In one possible implementation, in the display substrate provided by embodiments of the present disclosure, the second isolation column and the first isolation column are provided symmetrically with respect to a center of the transition region.

In one possible implementation, in the display substrate provided by embodiments of the present disclosure, a third isolation column extending in an extension direction of the connecting bridge region is provided in a side portion of the connecting bridge region close to the aperture region, wherein the third isolation column includes at least a part of film layers among the blocking layer, the buffer layer, the passivation layer, the first inorganic encapsulation layer, or the second inorganic encapsulation layer.

In one possible implementation, in the display substrate provided by embodiments of the present disclosure, the third isolation column includes the blocking layer, the buffer layer, the first flat layer, the second flat layer, the passivation layer, the first inorganic encapsulation layer, and the second inorganic encapsulation layer.

In one possible implementation, in the display substrate provided by embodiments of the present disclosure, the third isolation column includes the blocking layer, the buffer layer, the first flat layer and the second flat layer.

In one possible implementation, in the display substrate provided by embodiments of the present disclosure, a side portion of the third isolation column close to the aperture region is immediately adjacent to the aperture region.

In one possible implementation, in the display substrate provided by embodiments of the present disclosure, a side portion of the third isolation column close to the aperture region is provided with a second preset distance from the aperture region.

In one possible implementation, in the display substrate provided by embodiments of the present disclosure, the second preset distance is in a range of 1 μm to 3 μm.

In one possible implementation, in the display substrate provided by embodiments of the present disclosure, a fourth isolation column extending in the extension direction of the connecting bridge region is provided in another side portion of the connecting bridge region close to the aperture region, wherein the fourth isolation column has the same film layer structure as the third isolation column.

In one possible implementation, in the display substrate provided by embodiments of the present disclosure, the fourth isolation column and the third isolation column are provided symmetrically with respect to a center of the connecting bridge region.

In one possible implementation, in the display substrate provided by embodiments of the present disclosure, the third isolation column and the first isolation column are provided on the same side and the third isolation column and the first isolation column are disconnected from each other.

In one possible implementation, the spacer is provided in a side portion of the pixel island region close to the connecting bridge region, and/or the spacer is provided in a side portion of the connecting bridge region close to the pixel island region.

In one possible implementation, in the display substrate provided by embodiments of the present disclosure, a number of the spacers provided in each pixel island region and the connecting bridge region connecting to the pixel island region is in a range of 1 to 4.

In one possible implementation, in the display substrate provided by embodiments of the present disclosure, the display substrate further includes: an anode between the passivation layer and the pixel definition layer, an organic light emitting layer between the pixel definition layer and the first inorganic encapsulation layer, and a cathode between the organic light emitting layer and the first inorganic encapsulation layer; and
a second partition groove is provided at a position of the pixel region close into the transition region, wherein the organic light emitting layer is disconnected at the second partition groove, the cathode is disconnected at the second partition groove, and the first inorganic encapsulation layer covers the second partition groove.

In one possible implementation, in the display substrate provided by embodiments of the present disclosure, the second partition groove penetrates through at least a part of the passivation layer and the second flat layer, a side portion of the passivation layer close to the second partition groove protrudes out of a side portion of the second flat layer close to the second partition groove, and he second partition groove is a closed structure around the transition region.

In one possible implementation, in the display substrate provided by embodiments of the present disclosure, the display substrate further includes: a first gate metal layer between the first gate insulating layer and the second gate insulating layer, a second gate metal layer between the second gate insulating layer and the interlayer insulating layer, a first source-drain metal layer between the interlayer insulating layer and the first flat layer, and a second source-drain metal layer between the first flat layer and the second flat layer; and
at least one sub-pixel is provided in the pixel island region, and the display substrate further includes a plurality of signal lines, which are provided in the connecting bridge region, extend into the pixel island region, and are electrically connected to the at least one sub-pixel; wherein
the plurality of signal lines include a first signal line and a second signal line stacked; wherein a portion of the first signal line in the pixel island region is provided in the first gate metal layer, a portion of the first signal line in the connecting bridge region is provided in the first source-drain metal layer, a portion of the second signal line in the pixel island region is provided in the second gate metal layer, and a portion of the second signal line in the connecting bridge region is provided in the second source-drain metal layer.

Accordingly, embodiments of the present disclosure also provide a display substrate including a plurality of pixel island regions, a plurality of aperture regions, and a plurality of connecting bridge regions, wherein each of the pixel island regions includes a transition region connected to a connecting bridge region and a pixel region; and a first isolation column including at least a part of inorganic film layers is provided in at least one side portion of a transition region close to an aperture region.

Accordingly, embodiments of the present disclosure also provide a display substrate including: a plurality of pixel island regions, a plurality of aperture regions, and a plurality of connecting bridge regions, wherein a third isolation column including at least a part of inorganic film layers extending in an extension direction of the connecting bridge region is provided in a connecting bridge region close to an aperture region.

Accordingly, embodiments of the present disclosure also provide a display substrate including: a plurality of pixel island regions, a plurality of aperture regions, and a plurality of connecting bridge regions, wherein each of the pixel island regions includes a transition region connected to a connecting bridge region and a pixel region; wherein
a first isolation column including at least a part of inorganic film layers is provided in at least one side portion of a transition region close to an aperture region, and a third isolation column including at least a part of inorganic film layers extending in an extension direction of the connecting bridge region is provided in a connecting bridge region close to an aperture region.

Accordingly, embodiments of the present disclosure also provide a display apparatus including the display substrate provided by the embodiments of the present disclosure.

Accordingly, embodiments of the present disclosure also provide a method for preparing a display substrate, which is used for preparing the above display substrate provided by the embodiments of the present disclosure, wherein the method for preparing the base substrate includes:
forming the plurality of pixel island regions, the plurality of aperture regions, and the plurality of connecting bridge regions on the base substrate, wherein each of the pixel island region includes the transition region connected with the connecting bridge region and a pixel region; and
forming the first gate insulating layer, the second gate insulating layer and the interlayer insulating layer that are sequentially stacked in a direction away from the base substrate; wherein the orthographic projections of the first gate insulating layer, the second gate insulating layer and the interlayer insulating layer on the base substrate each cover the pixel region and extend into the transition region; wherein along the direction of the pixel island region pointing toward the connecting bridge region, the first gate insulating layer, the second gate insulating layer and the interlayer insulating layer have different cutoff positions in the transition region.

### BRIEF DESCRIPTION OF FIGURES

FIG. 1 is a schematic diagram of a planar structure of a display substrate provided by embodiments of the present disclosure.

FIG. 2A is a schematic diagram of a partially enlarged structure in FIG. 1.

FIG. 2B is a schematic diagram of another partially enlarged structure in FIG. 1.

FIG. 3 is a schematic diagram of a sectional structure along a direction AA′ in FIGS. 2A and 2B.

FIG. 4 is a schematic diagram of another sectional structure along a direction AA′ in FIGS. 2A and 2B.

FIG. 5 is a schematic diagram of yet another sectional structure along a direction AA′ in FIGS. 2A and 2B.

FIG. 6 is a schematic diagram of a sectional structure along a direction DD′ in FIG. 2A.

FIG. 7 is a schematic diagram of another sectional structure along a direction DD′ in FIG. 2A.

FIG. 8 is a schematic diagram of yet another sectional structure along a direction DD′ in FIG. 2B.

FIG. 9 is a schematic diagram of yet another sectional structure along a direction DD′ in FIG. 2B.

FIG. 10 is a schematic diagram of yet another sectional structure along a direction DD′ in FIG. 2A.

FIG. 11 is a schematic diagram of yet another sectional structure along a direction DD′ in FIG. 2A.

FIG. 12 is a schematic diagram of yet another sectional structure along a direction DD′ in FIG. 2B.

FIG. 13 is a schematic diagram of yet another sectional structure along a direction DD′ in FIG. 2B.

FIG. 14 is a schematic diagram of yet another sectional structure along a direction DD′ in FIG. 2A.

FIG. 15 is a schematic diagram of yet another sectional structure along a direction DD′ in FIG. 2A.

FIG. 16 is a schematic diagram of yet another sectional structure along a direction DD′ in FIG. 2B.

FIG. 17 is a schematic diagram of yet another sectional structure along a direction DD′ in FIG. 2B.

FIG. 18 is a schematic diagram of yet another sectional structure along a direction DD′ in FIG. 2A.

FIG. 19 is a schematic diagram of yet another sectional structure along a direction DD′ in FIG. 2A.

FIG. 20 is a schematic diagram of yet another sectional structure along a direction DD′ in FIG. 2B.

FIG. 21 is a schematic diagram of yet another sectional structure along a direction DD′ in FIG. 2B.

FIG. 22 is a schematic diagram of a sectional structure along a direction CC′ in FIG. 2A.

FIG. 23 is a schematic diagram of another sectional structure along a direction CC′ in FIG. 2B.

FIG. 24 is a schematic diagram of yet another sectional structure along a direction CC′ in FIG. 2A.

FIG. 25 is a schematic diagram of yet another sectional structure along a direction CC′ in FIG. 2B.

FIG. 26 is a schematic diagram of yet another sectional structure along a direction CC′ in FIG. 2A.

FIG. 27 is a schematic diagram of yet another sectional structure along a direction CC′ in FIG. 2B.

FIG. 28 is a schematic diagram of yet another sectional structure along a direction CC′ in FIG. 2A.

FIG. 29 is a schematic diagram of yet another sectional structure along a direction CC′ in FIG. 2B.

FIG. 30 is a schematic diagram of yet another sectional structure along a direction CC′ in FIG. 2B.

FIG. 31 is a schematic diagram of yet another partially enlarged structure in FIG. 1.

FIG. 32 is a schematic diagram of yet another partially enlarged structure in FIG. 1.

FIG. 33 is a schematic diagram of a pixel circuit of 2T1C.

FIG. 34 is a schematic diagram of a pixel circuit of 3T1C.

FIG. 35 is a schematic diagram of a pixel circuit of 7T1C.

FIG. 36 is a schematic diagram of yet another sectional structure along a direction AA′ in FIGS. 2A and 2B.

FIG. 37 is a flow chart of a method for preparing a display substrate provided by embodiments of the present disclosure.

FIG. 38A is a schematic diagram of structures of a display substrate corresponding fabrication processes, respectively, provided by embodiments of the present disclosure.

FIG. 38B is a schematic diagram of structures of a display substrate corresponding fabrication processes, respectively, provided by embodiments of the present disclosure.

FIG. 38C is a schematic diagram of structures of a display substrate corresponding fabrication processes, respectively, provided by embodiments of the present disclosure.

FIG. 39A is a schematic diagram of structures of a display substrate corresponding fabrication processes, respectively, provided by embodiments of the present disclosure.

FIG. 39B is a schematic diagram of structures of a display substrate corresponding fabrication processes, respectively, provided by embodiments of the present disclosure.

FIG. 40A is a schematic diagram of structures of a display substrate corresponding fabrication processes, respectively, provided by embodiments of the present disclosure.

FIG. 40B is a schematic diagram of structures of a display substrate corresponding fabrication processes, respectively, provided by embodiments of the present disclosure.

FIG. 41A is a schematic diagrams of structures of a display substrate corresponding fabrication processes, respectively, provided by embodiments of the present disclosure.

FIG. 41B is a schematic diagrams of structures of a display substrate corresponding fabrication processes, respectively, provided by embodiments of the present disclosure

FIG. 42A is a schematic diagram of structures of a display substrate corresponding fabrication processes, respectively, provided by embodiments of the present disclosure.

FIG. 42B is a schematic diagram of structures of a display substrate corresponding fabrication processes, respectively, provided by embodiments of the present disclosure.

FIG. 43 is a schematic diagram of a structure of a display substrate corresponding to a fabrication process provided by embodiments of the present disclosure.

FIG. 44A is a schematic diagram of structures of a display substrate corresponding fabrication processes, respectively, provided by embodiments of the present disclosure.

FIG. 44B is a schematic diagram of structures of a display substrate corresponding fabrication processes, respectively, provided by embodiments of the present disclosure.

FIG. 45A is a schematic diagram of structures of a display substrate corresponding fabrication processes, respectively, provided by embodiments of the present disclosure.

FIG. 45B is a schematic diagram of structure of a display substrate corresponding fabrication processes, respectively, provided by embodiments of the present disclosure.

FIG. 46A is a schematic diagram of structures of a display substrate corresponding fabrication processes, respectively, provided by embodiments of the present disclosure.

FIG. 46B is a schematic diagram of structures of a display substrate corresponding fabrication processes, respectively, provided by embodiments of the present disclosure.

FIG. 47A is a schematic diagram of structures of a display substrate corresponding fabrication processes, respectively, provided by embodiments of the present disclosure.

FIG. 47B is a schematic diagram of structures of a display substrate corresponding fabrication processes, respectively, provided by embodiments of the present disclosure.

FIG. 48A is a schematic diagram of structures of a display substrate corresponding fabrication processes, respectively, provided by embodiments of the present disclosure.

FIG. 48B is a schematic diagram of structures of a display substrate corresponding fabrication processes, respectively, provided by embodiments of the present disclosure.

FIG. 48C is a schematic diagram of structures of a display substrate corresponding fabrication processes, respectively, provided by embodiments of the present disclosure.

FIG. 49 is a schematic diagram of a structure of a display substrate corresponding to a fabrication process provided by embodiments of the present disclosure.

FIG. 50 is a schematic diagram of a structure of a display substrate corresponding to a fabrication process provided by embodiments of the present disclosure.

FIG. 51A is a schematic diagram of structures of a display substrate corresponding fabrication processes, respectively, provided by embodiments of the present disclosure.

FIG. 51B is a schematic diagram of structures of a display substrate corresponding fabrication processes, respectively, provided by embodiments of the present disclosure.

FIG. 52 is a schematic diagram of a structure of a display substrate corresponding to a fabrication process provided by embodiments of the present disclosure.

FIG. 53A is a schematic diagram of structures of a display substrate corresponding fabrication processes, respectively, provided by embodiments of the present disclosure.

FIG. 53B is a schematic diagram of structures of a display substrate corresponding fabrication processes, respectively, provided by embodiments of the present disclosure.

FIG. 53C is a schematic diagram of structures of a display substrate corresponding fabrication processes, respectively, provided by embodiments of the present disclosure.

### DETAILED DESCRIPTION

In order to make the objects, technical solutions and advantages of the embodiments of the present disclosure clearer, the technical solutions of the embodiments of the present disclosure will be described clearly and completely in the following in conjunction with the accompanying drawings of the embodiments of the present disclosure. Obviously, the described embodiments are a part of the embodiments of the present disclosure, and not all of the embodiments. In addition, the embodiments and the features in the embodiments of the present disclosure can be combined with each other without conflict. Based on the described embodiments of the present disclosure, all other embodiments obtained by a person of ordinary skill in the art without the need for creative labor are within the claimed scope of the present disclosure.

Unless otherwise defined, technical or scientific terms used in the present disclosure shall have the ordinary meaning understood by a person of ordinary skill in the field to which the present disclosure belongs. The words “including” or “comprising” and the like as used in the present disclosure are intended to mean that the component or object preceded by the word encompasses the components or objects listed after the word and their equivalents, and does not exclude other components or objects. Words such as “connected” or “coupled” are not limited to physical or mechanical connections, but may include electrical connections, whether direct or indirect. The words “inside”, “outside”, “above”, “below”, etc., are used only to indicate relative positional relationships. When the absolute position of the depicted object is changed, the relative positional relationship may also be changed accordingly.

It should be noted that the dimensions and shapes of the figures in the accompanying drawings do not reflect true proportions, but are intended to be illustrative of the invention only. And throughout the same or similar labeling denotes the same or similar elements or elements having the same or similar function.

The display substrate (e.g., stretchable display substrate) generally includes a pixel island region, a connecting bridge region, and an aperture region enclosed by the pixel island region and the connecting bridge region, wherein the light emitting structure and the driving circuit are placed in the pixel island region, and a signal connection is made between pixel island regions that are adjacent to each other via a metal wiring in the connecting bridge region. During the stretching process of the display substrate, the pixel island region is not deformed and the connecting bridge region undergoes a large deformation to realize a stress/strain isolation design for the devices in the pixel island region and to realize the stretching deformation capability of the island-bridge structure during the stretching process. However, during the stretching deformation process, there is usually a stress concentration at the connecting position between the pixel island region and the connecting bridge region, and thus the film layer, especially the inorganic film layer, is very susceptible to crack at the connecting position between the pixel island region and the connecting bridge region.

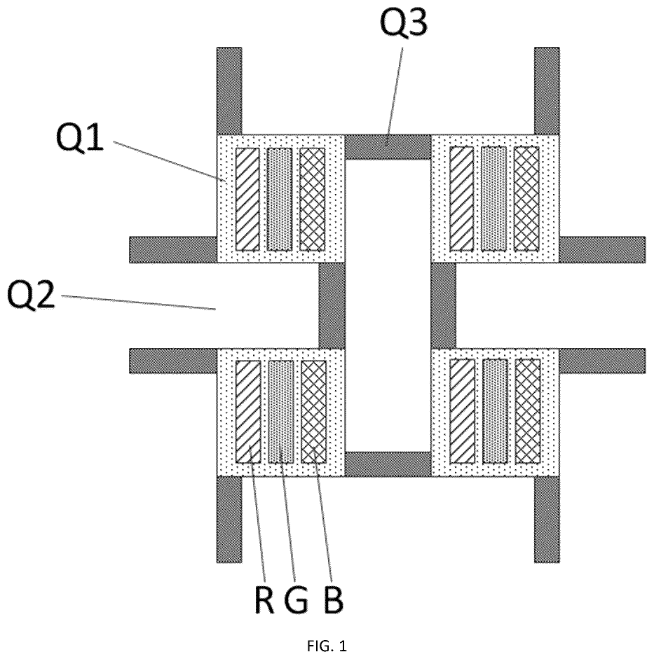

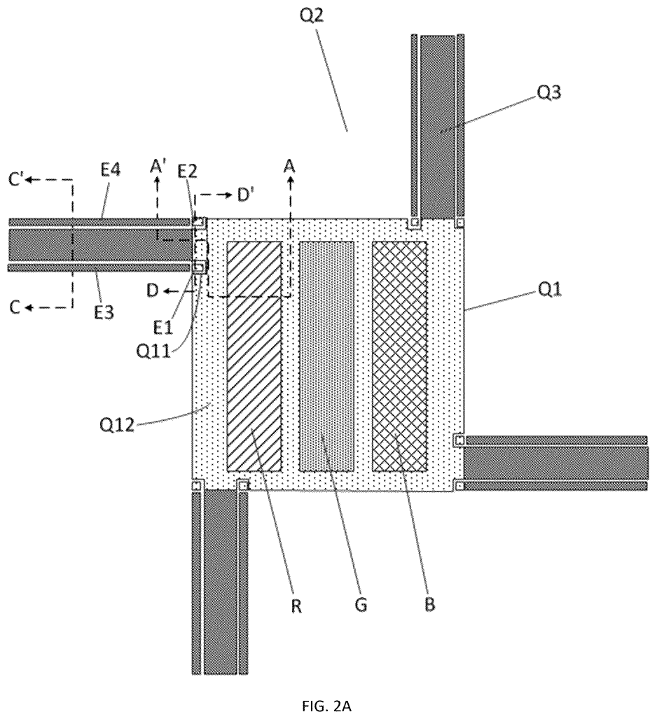

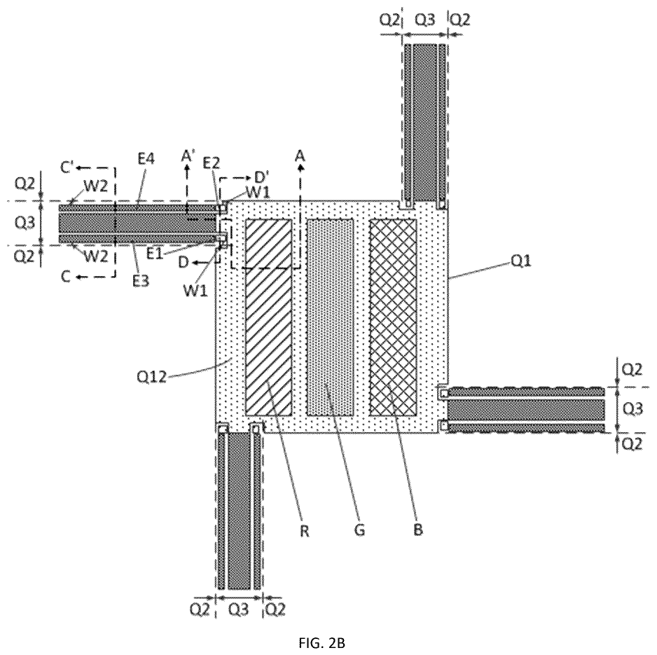

In order to solve the problem that the film layer is very susceptible to crack at the connecting position between the pixel island region and the connecting bridge region, the present disclosure provides a display substrate as shown in FIG. 1, FIG. 2A and FIG. 2B. FIG. 1 is a schematic diagram of a planar structure of the display substrate, FIG. 2A is a schematic diagram of a partially enlarged structure in FIG. 1, and FIG. 2B is a schematic diagram of another partially enlarged structure in FIG. 1. The display substrate includes a plurality of pixel island regions Q1, a plurality of aperture regions Q2, and a plurality of connecting bridge regions Q3. The pixel island region Q1 includes a transition region Q11 connected to the connecting bridge regions Q3 and a pixel region Q12. Specifically, the pixel island regions Q1 are used for displaying an image, the connecting bridge regions Q3 are used for routing wirings (so that signals between pixel island regions Q1 that are adjacent to each other are communicated) and transmitting a pulling force, and the aperture regions Q2 are used for providing a deformation space for the display substrate when it is stretched.

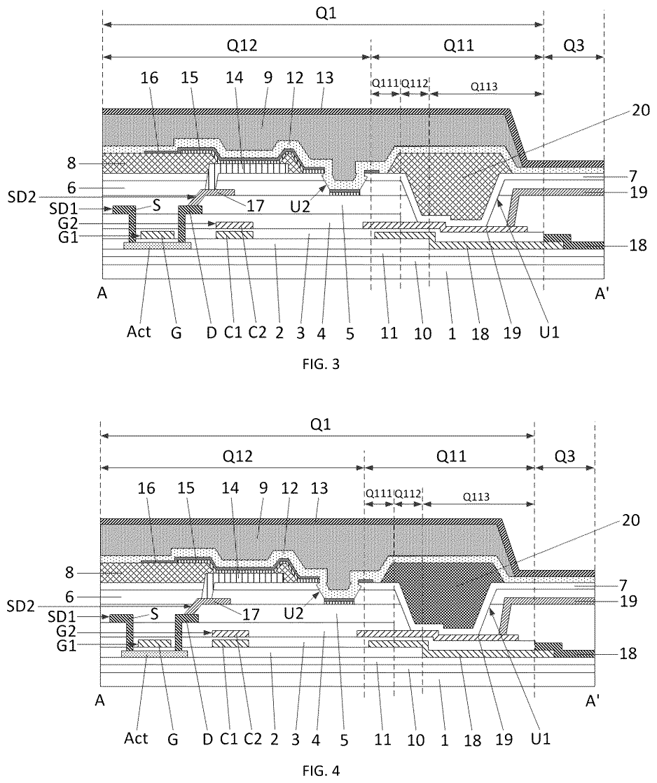

As shown in FIG. 3-FIG. 5, which are schematic diagrams of several sectional structures along the direction AA′ in FIG. 2A, respectively, the display substrate includes: a base substrate 1, and a first gate insulating layer 2, a second gate insulating layer 3, and an interlayer insulating layer 4 sequentially stacked along a direction away from the base substrate 1. Orthographic projections of the first gate insulating layer 2, the second gate insulating layer 3, and the interlayer insulating layer 4 on the base substrate 1 each covers the pixel region Q12 and extends into the transition region Q11. Along a direction of the pixel island region Q1 pointing towards the connecting bridge region Q3, the first gate insulating layer 2, the second gate insulating layer 3 and the interlayer insulating layer 4 have different cutoff positions in the transition region Q11, i.e., boundaries of the orthographic projections of the first gate insulating layer 2, the second gate insulating layer 3 and the interlayer insulating layer 4 on the transition region Q11 of the base substrate 1 do not overlap with each other.

The above display substrate provided by the embodiments of the present disclosure, by setting the cutoff positions of the first gate insulating layer, the second gate insulating layer, and the interlayer insulating layer in the transition region to be different from each other, a design of rigidity gradient variation in the transition region from the pixel island region to the connecting bridge region can be realized, which reduce the risk of a crack at the island-bridge connecting position in the stretching process.

Specifically, as shown in FIGS. 1, 2A, and 2B, the pixel region Q12 of each pixel island region Q1 includes at least one sub-pixel, and the sub-pixel includes a light emitting structure and a driving circuit. FIGS. 1, 2A, and 2B provided by the present disclosure takes each pixel island region Q1 including three sub-pixels as an example, and the three sub-pixels may be a red sub-pixel R, a green sub-pixel G, and a blue sub-pixel B, respectively, and of course is not be limited thereto.

Specifically, as shown in FIG. 3-FIG. 5, the base substrate 1 may be a flexible substrate to enable the stretchable region of the display substrate to be stretched. The base substrate 1 may include a single flexible layer, or may include a first flexible layer, a barrier layer, and a second flexible layer stacked. In embodiments of the present disclosure, an example of the base substrate 1 including a single flexible layer is used. Specifically, the material of the flexible layer may be polyimide (PI), polyester, polyamide, and the like.

Specifically, as shown in FIG. 3-FIG. 5, the base substrate 1 and the film layer thereon may be provided on a glass substrate having a supporting role, and the glass substrate is peeled off after the film layers are prepared to obtain a stretchable display substrate.

It should be noted that, as shown in FIGS. 1, 2A, and 2B, in the embodiments of the present disclosure, the aperture region Q2 may be completely penetrated through the display substrate, and of course, the aperture region Q2 may also be penetrated through at least part of film layers on the base substrate 1 as well as a part of the base substrate 1. The embodiments of the present disclosure are based on an example that the aperture region Q2 is completely penetrated through the display substrate.

In specific implementation, in the above display substrate provided by the present embodiments of the disclosure, as shown in FIG. 3-FIG. 5, the display substrate further includes a first flat layer 5, a second flat layer 6, and a passivation layer 7 sequentially stacked on one side of the interlayer insulating layer 4 way from the base substrate 1. Orthographic projections of the first flat layer 5 and the second flat layer 6 on the base substrate 1 each cover the pixel island region Q1 and the connecting bridge region Q3, and an orthographic projection of the passivation layer 7 on the base substrate 1 at least covers the pixel island region Q1.

In a specific implementation, in the above display substrate provided by the embodiments of the present disclosure, as shown in FIG. 3-FIG. 5, the display substrate further includes: a pixel definition layer 8, a spacer (not shown), and an organic encapsulation layer 9 sequentially stacked on the side of the passivation layer 7 away from the base substrate 1, a blocking layer 10 between the base substrate 1 and the first gate insulating layer 2, a buffer layer 11 between the blocking layer 10 and the first gate insulating layer 2, a first inorganic encapsulation layer 12 between the spacer and the organic encapsulation layer 9, and a second inorganic encapsulation layer 13 on one side of the organic encapsulation layer 9 away from the base substrate 1. An orthographic projection of the organic encapsulation layer 9 on the base substrate 1 covers the pixel island region Q1 and a boundary of the orthographic projection cuts off on one side close to the connecting bridge region Q3. Through the first inorganic encapsulation layer 12, the organic encapsulation layer 9, and the second inorganic encapsulation layer 13, the water vapor from the external environment can be reduced to invade the light emitting device of the sub-pixel, so as to reduce the probability of failure of the light emitting device.

In specific implementation, in the above display substrate provided by embodiments of the present disclosure, as shown in FIGS. 3-5, an anode 14 between the passivation layer 7 and the pixel definition layer 8 is provided in the pixel island region Q1, the pixel definition layer 8 has a pixel opening to expose the anode 14, and a cathode 16, which is between the pixel definition layer 8 and the first inorganic encapsulation layer 12, at least covers an organic light emitting layer in the pixel opening and is between the organic light emitting layer 15 and the first inorganic encapsulation layer 12, is further provided in the pixel island region Q1. The anode 14, the organic light emitting layer 15, and the cathode 16 form a light emitting device.

In a specific implementation, in the above display substrate provided by the embodiments of the present disclosure, as shown in FIGS. 3-5, the display substrate further includes: a first gate metal layer G1 between the first gate insulating layer 2 and the second gate insulating layer 3, a second gate metal layer G2 between the second gate insulating layer 3 and the interlayer insulating layer 4, a first source-drain metal layer SD1 between the interlayer insulating layer 4 and the first flat layer 5, and a second source-drain metal layer SD2 between the first flat layer 5 and the second flat layer 6. A driving circuit between the buffer layer 11 and the anode 14 is provided in the pixel island region Q1. The driving circuit includes a thin-film transistor and a storage capacitor. The thin-film transistor includes: an active layer Act between the buffer layer 11 and the first gate insulating layer 2, a gate G in the first gate metal layer G1, a source S and a drain D in the first source-drain metal layer SD1. The storage capacitor includes: a first electrode plate C1 in the first gate metal layer, and a second electrode plate C2 in the second gate metal layer. The second source-drain metal layer SD2 includes a lap joint portion 17, a data line, and the like, and the anode 14 is electrically connected to the lap joint portion 17 via a via hole sequentially penetrating through the passivation layer 7 and the second flat layer 6, and the lap joint portion 17 is electrically connected to the drain D through a via hole penetrating through the first flat layer 5.

In specific implementation, in the above display substrate provided by the embodiments of the present disclosure, as shown in FIG. 3-FIG. 5, the display substrate further includes a plurality of signal lines which are provided in the connecting bridge region Q3, extend into the pixel island region Q1, and are electrically connected to the sub-pixels. The plurality of signal lines includes a first signal line(s) 18 and a second signal line(s) 19. A portion of the first signal line 18 in the pixel island region Q1 is provided in the first gate metal layer G1, and a portion of the first signal line 19 in the connecting bridge region Q3 is provided in the first source-drain metal layer SD1. A portion of the second signal line 19 in the pixel island region Q1 is provided in the second gate metal layer G2, and a portion of the second signal line 19 in the connecting bridge region Q3 is provided in the second source-drain metal layer SD2.

In specific implementation, since the signals are communicated between the pixel island regions via metal wirings in the connecting bridge region, the metal wirings need to be led into the connecting bridge region through the transition region after the metal wirings are connected to the sub-pixels in the pixel island regions, and the metal wirings located in the pixel island regions generally go through the first gate metal layer (e.g., the first signal line) and the second gate metal layer (e.g., the second signal line). While the metal wiring in the pixel island region generally routes through the first source-drain metal layer (e.g., the first signal line) and the second gate metal layer (e.g., the second signal line), and then the first signal line at the position of the transition region close to the connecting bridge region is jumpered to the first source-drain metal layer, and the second signal line jumper at the position of the transition region close to the connecting bridge region is jumpered to the second source-drain metal layer. In order to avoid short-circuiting between the first signal line and the second signal line, in the above display substrate provided by the embodiments of the present disclosure, as shown in FIG. 3-FIG. 5, the cutoff position of the second gate insulating layer 3 between the first gate metal layer and the second gate metal layer in the transition region is provided to be immediately adjacent to the connecting bridge region Q3. The first gate metal layer G1 and the second gate metal layer G2 can be insulated from each other by the second gate insulating layer 3. The cutoff position of the first gate insulating layer 2 in the transition region Q11 and the cutoff position of the interlayer insulating layer 4 in the transition region Q11 are away from the connecting bridge region Q3. In this manner, a region of the transition region Q11 close to the pixel region Q12 is a three-layer stacked structure of the first gate insulating layer 2, the second gate insulating layer 3, and the interlayer insulating layer 4 and is provided with the greatest stiffness. A region of the transition region Q11 close to the connecting bridge region Q3 is a single-layer structure of the second gate insulating layer 3 and is provided with the least stiffness. A two-layer stacked structure of the first gate insulating layer 2 and the second gate insulating layer 3 or a two-layer stacked structure of the second gate insulating layer 3 and the interlayer insulating layer 4 is between the three-layer stacked structure and the single-layer structure, which realize the design of rigidity gradient variation in the transition region Q11 from the pixel island region Q1 to the connecting bridge region Q3, so as to reduce the risk of a crack at the island-bridge connecting position in the stretching process.

In specific implementation, in the above display substrate provided by the embodiments of the present disclosure, as shown in FIG. 3-FIG. 5, the transition region Q11 can be divided into a first region Q111, a second region Q112, and a third region Q113 along the direction of the pixel island region Q1 pointing toward the connecting bridge region Q3. The orthographic projection of the second gate insulating layer 3 on the base substrate 1 covers the orthographic projection of the transition region Q11 on the base substrate 1, i.e., the orthographic projection of the second gate insulating layer 3 on the base substrate 1 covers the orthographic projections of the first region Q111, the second region Q112 and the third region Q113 on the base substrate 1. The orthographic projection of the first gate insulating layer 2 on the base substrate 1 covers the orthographic projections of the first region Q111 and the second region Q112 on the base substrate 1. The orthographic projection of the interlayer insulating layer 4 on the base substrate 1 covers the orthographic projection of the first region Q111 on the base substrate 1. That is, when preparing the first gate insulating layer 2, the second gate insulating layer 3, and the interlayer insulating layer 4, the first gate insulating layer 2 in the third region Q113, the connecting bridge region Q3, and the aperture region Q2 is removed, the second gate insulating layer 3 in the connecting bridge region Q3 and the aperture region Q2 is removed, and the interlayer insulating layer 4 in the second region Q112, the third region Q113, the connecting bridge region Q3, and the aperture region Q2 is removed. In this manner, the first region Q111 of the transition region Q11 close to the pixel region Q12 is a three-layer stacked structure of the first gate insulating layer 2, the second gate insulating layer 3, and the interlayer insulating layer 4 and is provided with the greatest stiffness. The third region Q113 of the transition region Q11 close to the connecting bridge region Q3 is a single-layer structure of the second gate insulating layer 3 and is provided with the least stiffness. A two-layer stacked structure of the first gate insulating layer 2 and the second gate insulating layer 3 is the second region Q112 between the first region Q111 and the third region Q113, which realize the design of rigidity gradient variation in the transition region Q11 from the pixel island region Q1 to the connecting bridge region Q3, so as to reduce the risk of a crack at the island-bridge connecting position in the stretching process.

Of course, in specific implementation, it is also possible that the orthographic projection of the first gate insulating layer 2 on the base substrate 1 covers the orthographic projection of the first region Q111 on the base substrate 1, and the orthographic projection of the interlayer insulating layer 4 on the base substrate 1 covers the orthographic projections of the first region Q111 and the second region Q112 on the base substrate 1. In this manner, a two-layer stacked structure of the second gate insulating layer 3 and the interlayer insulating layer 4 is between the second region Q112 between the first region Q111 and the third region Q113, which can also realize the design of rigidity gradient variation in the transition region Q11 from the pixel island region Q1 to the connecting bridge region Q3.

Optionally, as shown in FIG. 3-FIG. 5, the width of the first region Q111, the width of the second region Q112, and the width of the third region Q113 may be equidistantly distributed, or of course, may not be equal, the design of which may be carried out according to the actual needs.

Specifically, as shown in FIG. 3-FIG. 5, the first signal line 18 in the first gate metal layer G1 in the pixel island region Q1 is jumpered at the connecting bridge region Q3 to the first source-drain metal layer SD1, and the second signal line 19 in the second gate metal layer G2 in the pixel island region Q1 is jumpered at a position of the third region Q113 close to the connecting bridge region Q3 to the second source-drain metal layer SD2 through a via hole penetrating through the first flat layer 5. Optionally, the first signal line 18 may be a power line (e.g., VDD, VSS), a gate line, and the like, and the second signal line 19 may be a data line, a sense signal line, and the like.

Specifically, as shown in FIG. 3-FIG. 5, since the boundary of the orthographic projection of the first gate insulating layer 2 cuts off at the second region Q112, when the first signal line 18 extends from the pixel region Q12 into the third region Q113, the first signal line 18 is formed with a first step structure at the junction of the second region Q112 and the third region Q113, and thus the subsequently prepared film layers such as the gate insulating layer 3 and the second signal line 19 are also formed with step structures at the position of the first step structure. Since the second signal line 19 is jumpered to the second source-drain metal layer SD2 at a position of the third region Q113 close to the connecting bridge region Q3 through a via hole penetrating through the first flat layer 5, the second signal line 19 is formed with a second step structure at the position of the via hole through the first flat layer 5. Since the thickness of the first flat layer 5 is generally higher than the height of the first gate insulation layer 2, the height of the second step structure of the second signal line 19 formed at the position of the via hole penetrating through the first flat layer 5 is higher than the height of the first step structure.

It should be noted that the jumpering line manners of the first signal line 18 and the second signal line 19 are not limited to the above jumpered from G1 to SD1 and from G2 to SD2, but may also be jumpered from G1 to SD1 and then from SD1 to SD2, and the like.

In some embodiments, as shown in FIG. 3-FIG. 5, the orthographic projection of the first signal line 18 on the base substrate 1 is at least partially overlapped with the orthographic projection of the second signal line 19 on the base substrate 1, and the edge of the orthographic projection of the first signal line 18, that is close to the base substrate 1, on the base substrate 1 is closer to the connecting bridge region Q3 than the edge of the orthographic projection of the second signal line 19 on the base substrate 1, which is so conducive to ensuring that the second signal line 19 will not be easily broken during the stretching process.

In some embodiments, as shown in FIG. 3-FIG. 5, the first signal line 18 in the first gate metal layer G1 in the pixel island region Q1 is jumpered at the connecting bridge region Q3 to the first source-drain metal layer SD1, and the second signal line 19 in the second gate metal layer in the pixel island region Q1 is jumpered at a position of the third region Q113 close to the connecting bridge region Q3 to the second source-drain metal layer SD2 through a via hole penetrating through the first flat layer 5. The jumpering line position of the first signal line 18 in the connecting the bridge region Q3 is staggered with the jumpering position of the second signal line 19 at the via hole, so as to facilitate the improvement of the yield rate, and simultaneously to facilitate the dispersion of the stress according to the position of the jumpering position during the stretchable process. In some embodiments, as shown in FIG. 3-FIG. 5, the first signal line 18 in the first gate metal layer G1 in the pixel island region Q1 is jumpered at the connecting bridge region Q3 to the first source-drain metal layer SD1, and the second signal line 19 in the second gate metal layer G2 in the pixel island region Q1 is jumpered at a position of the third region Q113 close to the connecting bridge region Q3 to the second source-drain metal layer SD2 through a via hole penetrating through the first flat layer 5. The spacing between the first signal line 18 and the second signal line 19 in the connecting bridge region Q3 is greater than the spacing between the first signal line 18 and the second signal line 19 in the pixel island region Q1 (e.g., the second gate insulating layer 3, the interlayer insulating layer 4, the first flat layer 5 are provided between the first signal line 18 and the second signal line 19 in the connecting bridge region Q3, the second gate insulating layer 3 is provided between the first signal line 18 and the second signal line 19 in the pixel island region Q1), such a design is conducive to ensuring that the first signal line 18 and the second signal line 19 do not interfere with each other in the signal transmission in the connecting bridge region Q3, and simultaneously ensuring that they will not be broken due to the first signal line 18 and the second signal line 19 being stretched more frequently in the connecting bridge region Q3.

In specific implementation, in the above display substrate provided by the embodiments of the present disclosure, as shown in FIG. 3-FIG. 5, the first flat layer 5 and the second flat layer 6 have a first partition groove U1 penetrating through the first flat layer 5 and the second flat layer 6 in the transition region Q11. The first partition groove U1 avoids the infiltration of water vapor in the first flat layer 5 and the second flat layer 6 in the connecting bridge region Q3 from the transition region Q11 to the pixel island region Q1. The passivation layer 7 covers the first partition groove U1, i.e., the passivation layer 7 covers the pixel island region Q1, the transition region Q11, and the connecting bridge region Q3. The passivation layer 7 at the transition region Q11 covers the both sidewalls of the first partition groove U1, and is in direct contact with the portion of the second signal line 19 in the transition region Q11. The passivation layer 7 is formed with a step structure at a position of the step structure of the second signal line 19 formed in the third region Q113. In order to solve the problem of a large difference in the stiffness matching at the position of the stack of film layers in the transition region Q11, the pixel region Q12, and the connecting bridge region Q3, the first partition groove U1 above the passivation layer 7 is filled with an organic compensation layer 20, so as to make the overall thickness of the transition region Q11 consistent with the overall thickness of the pixel region Q12 of the pixel island region Q1, which avoids a large sudden change in stiffness at the transition region Q11, and further reduces the risk of crack at the island-bridge connecting position during the stretching process.

In some embodiments, in the above display substrate provided by embodiments of the present disclosure, as shown in FIG. 3, the orthographic projection of the organic compensation layer 20 on the base substrate 1 is overlapped with each of the orthographic projections the first gate insulating layer 2, the second gate insulating layer 3, and the interlayer insulating layer 4 on the base substrate 1. The orthographic projection of the organic compensation layer 20 on the base substrate 1 is within the orthographic projection of the second gate insulating layer 3 on the base substrate 1.

In some embodiments, in the above display substrate provided by the embodiments of the present disclosure, as shown in FIG. 3, the overlapping area of the orthographic projection of the organic compensation layer 20 on the base substrate 1 and the orthographic projection of the second gate insulating layer 3 on the base substrate 1 is larger than the overlapping area of the orthographic projection of the organic compensation layer 20 on the base substrate 1 and the orthographic projection of the first gate insulating layer 2 on the base substrate 1. The center of gravity of the organic compensation layer 20 is close to the edge of the second gate insulating layer 3 (the center of gravity of the organic compensation layer 20 is located substantially in the portion of the second gate insulating layer 3 exceeding the edge of the first gate insulating layer 2), i.e., a majority of the weight of the organic compensation layer 20 is located in the portion of the second gate insulating layer 3 exceeding the edge of the first gate insulating layer 2, which is conducive to fixing the organic compensation layer 20 as well as the subsequent encapsulation layer.

In specific implementation, in the above display substrate provided by the embodiments of the present disclosure, as shown in FIG. 3, the organic compensation layer 20 may be made of the same material as the pixel definition layer 8. In this manner, the patterns of the organic compensation layer 20 and the pixel definition layer 8 can be formed by one patterning process without adding a separate process for preparing the organic compensation layer 20, which can simplify the preparation process, save production costs, and improve production efficiency.

In specific implementation, in the above display substrate provided by the embodiments of the present disclosure, as shown in FIG. 4, the organic compensation layer 20 may be made of the same material as the spacer. In this manner, the patterns of the organic compensation layer 20 and the spacer can be formed by one patterning process without adding a separate process for preparing the organic compensation layer 20, which can simplify the preparation process, save production costs, and improve production efficiency.

Optionally, as shown in FIGS. 3 and 4, the surface of the organic compensation layer 20 away from the base substrate 1 may be set approximately flush with the surface of the pixel definition layer 8 away from the base substrate 1, so that the overall thickness of the transition region Q11 is approximately the same as the overall thickness of the pixel region Q12 of the pixel island region Q1.

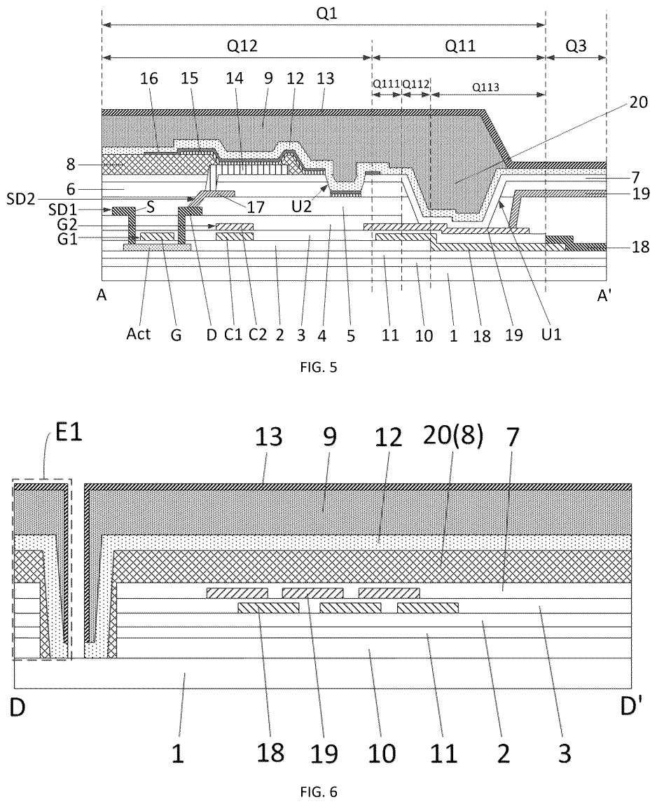

In specific implementation, in the above display substrate provided by embodiments of the present disclosure, as shown in FIG. 5, the organic compensation layer 20 may be made of the same material as the organic encapsulation layer 9. In this manner, the organic material is utilized to fill the first partition groove U1 when forming the organic encapsulation layer 9, and thus there is also no need to add a separate process for preparing the organic compensation layer 20, which can simplify the preparation process, save production costs, and improve production efficiency.

In some embodiments, as shown in FIG. 5, the organic compensation layer 20 may be made of the same material as the organic encapsulation layer 9, i.e., the thickness of the organic encapsulation layer 9 in a position close to the connecting bridge region Q3 is greater than the thickness of the organic encapsulation layer 9 in the pixel island region Q1, e.g., the thickness of the organic encapsulation layer 9 in a position close to the connecting bridge region Q3 is greater than the height from the second source-drain metal layer SD2 (e.g., the second source-drain metal layer includes the lap joint portion 17, data lines) to the second inorganic encapsulation layer 13.

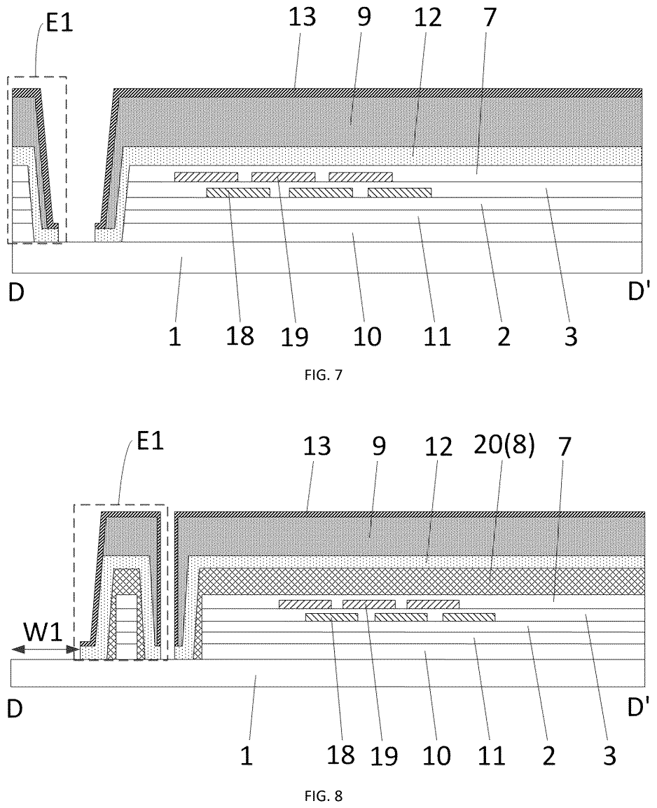

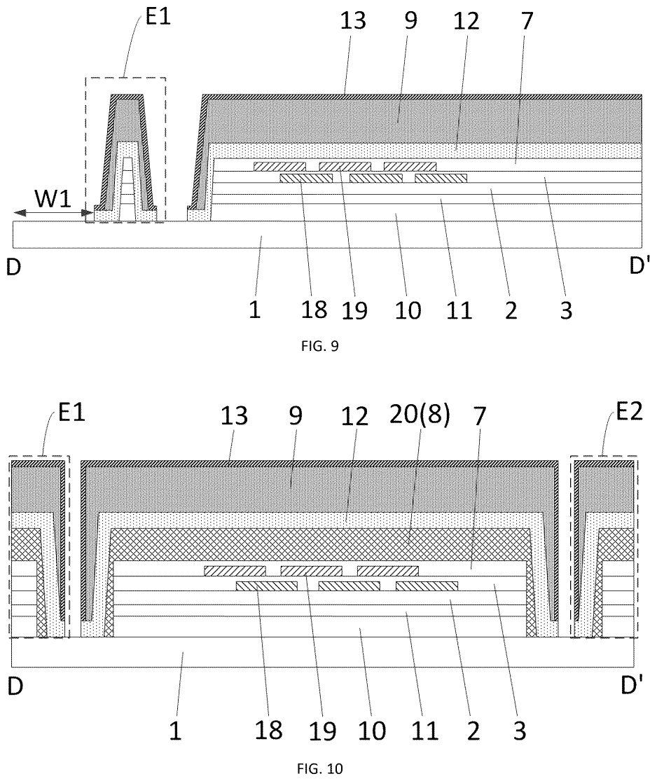

In specific implementation, as shown in FIG. 2A and FIG. 2B, during the stretching process of the display substrate, the side portions of the transition region Q11 close to the aperture region Q2 tend to be the starting position for forming the crack. In order to enhance the stretching deformation capability of the display substrate, in the above display substrate provided by the embodiments of the present disclosure, as shown in FIG. 2A, FIG. 2B, and FIG. 6-FIG. 9, FIG. 6 and FIG. 7 each show schematic diagrams of two sectional structures of the display substrate in FIG. 2A along the direction DD′, and FIGS. 8 and 9 each are schematic diagrams of portions of the two sectional structures along the direction DD′ in FIG. 2B. A first isolation column E1 is provided at a side portion (e.g., point D) of the transition region Q11 close to the aperture region Q2. The first isolation column E1 includes at least a part of film layers among the blocking layer 10, the buffer layer 11, the first gate insulating layer 2, the second gate insulating layer 3, the passivation layer 7, the first inorganic encapsulation layer 12 or the second inorganic encapsulation layer 13. By designing the first isolation column E1 including at least a part of inorganic film layer at a boundary position (e.g., point D) of the transition region Q11 close to the aperture region Q2, the inorganic film layer(s) in the first isolation column E1 is physically isolated from the inorganic film layer(s) in the transition region Q11 away from the aperture region Q2 and the pixel region Q12 in the direction DD′ by a process such as photolithography/etching, so as to avoid that, during the stretching process, the inorganic film layer(s) (e.g., at point D) close to the side of the aperture region Q2 is formed with a crack developing and extending along the direction from D to D′. The first isolation column E1 has the effect of blocking the extension of the crack of the inorganic film layer at the junction of the pixel island region Q1 and the connecting bridge region Q3, which reduces the risk of disconnection of the metal signal line at the connecting position and the crack of the inorganic film layer in the pixel island region Q1, and improves the stretching deformation capability of the display substrate.

In specific implementation, in the above display substrate provided by the embodiments of the present disclosure, as shown in FIG. 2A, FIG. 2B, FIG. 3, FIG. 6, and FIG. 8, when the organic compensation layer 20 and the pixel definition layer 8 have the same material, the first isolation column E1 may include the blocking layer 10, the buffer layer 11, the first gate insulating layer 2, the second gate insulating layer 3, the passivation layer 7, the organic compensation layer 20 (pixel definition layer 8), the first inorganic encapsulation layer 12, the organic encapsulation layer 9 and the second inorganic encapsulation layer 13. In this manner, all the inorganic film layers and organic film layers at the side portion of the transition region Q11 close to the aperture region Q2 are physically isolated from the inorganic film layers and organic film layers away from the aperture region Q2 by the first isolation column E1, which can completely block the effect of the extension of the crack of the inorganic film layers, thereby further enhancing the stretching deformation capability of the display substrate.

In specific implementation, in the above display substrate provided by embodiments of the present disclosure, as shown in FIG. 2A, FIG. 2B, FIG. 4, FIG. 6, and FIG. 8, when the organic compensation layer 20 and the spacer have the same material, the first isolation column E1 may include the blocking layer 10, the buffer layer 11, the first gate insulating layer 2, the second gate insulating layer 3, the passivation layer 7, an organic compensation layer 20 (a spacer), the first inorganic encapsulation layer 12, the organic encapsulation layer 9, and the second inorganic encapsulation layer 13.

Specifically, as shown in FIG. 2A and FIG. 6, the orthographic projections of the first side edges of the film layers in the first isolation column E1 on the base substrate 1 at the side portion (e.g., at point D) of the transition region Q11 close to the aperture region Q2 may be overlapped with each other, which of course refers to only overlap, and there may be a certain deviation. A side portion of the organic compensation layer 20 (spacer) in the first isolation column E1 away from the aperture region Q2 can cover the blocking layer 10, the buffer layer 11, the first gate insulating layer 2, the second gate insulating layer 3, the passivation layer 7, and is in contact with the base substrate 1. A side portion of the first inorganic encapsulation layer 12 in the first isolation column E1 away from the aperture region Q2 can cover the organic compensation layer 20 and is in contact with the base substrate 1. A side portion of the organic encapsulation layer 9 in the first isolation column E1 away from the aperture region Q2 can cover part of the side edge of the first inorganic encapsulation layer 12 away from the aperture region Q2 away from the aperture region Q2. A side portion of the second inorganic encapsulation layer 13 in the first isolation column E1 away from the aperture region Q2 can cover part of the side edge of the organic encapsulation layer 9 away from the aperture region Q2.

Specifically, as shown in FIGS. 2B and 8, the orthographic projections of the blocking layer 10, the buffer layer 11, the first gate insulating layer 2, the second gate insulating layer 3, and the passivation layer 7 in the first isolation column E1 on the base substrate 1 may be substantially overlapped with each other. The organic compensation layer 20 in the first isolation column E1 may wrap the blocking layer 10, the buffer layer 11, the first gate insulating layer 2, the second gate insulating layer 3, and the passivation layer 7 and be in contact with the base substrate 1. The first inorganic encapsulation layer 12 in the first isolation column E1 can wrap the organic compensation layer 20 and be in contact with the base substrate 1. A side away from the aperture region Q2, of the organic encapsulation layer 9 in the first isolation column E1 can cover part of the side edge of the first inorganic encapsulation layer 12 away from the aperture region Q2. The orthographic projection of the second inorganic encapsulation layer 13 in the first isolation column E1 on the base substrate 1 can cover the orthographic projection of the organic encapsulation layer 9 on the base substrate 1.

In specific implementation, in the above display substrate provided by the embodiments of the present disclosure, as shown in FIG. 2A, FIG. 2B, FIG. 5, FIG. 7, and FIG. 9, when the organic compensation layer 20 and the organic encapsulation layer 9 have the same material, the first isolation column E1 may include the blocking layer 10, the buffer layer 11, the first gate insulating layer 2, the second gate insulating layer 3, the passivation layer 7, the first inorganic encapsulation layer 12, the organic encapsulation layer 9, and the second inorganic encapsulation layer 13.

Specifically, as shown in FIGS. 2A and 7, the orthographic projections of the first side edges of the film layers in the first isolation column E1 on the base substrate 1 at the side portion (e.g., at point D) of the transition region Q11 close to the aperture region Q2 may be overlapped with each other, which of course refers to only overlap, and there may be a certain deviation. A side away from the aperture region Q2, of the first inorganic encapsulation layer 12 in the first isolation column E1 can cover the side edges away from the aperture region Q2, of the blocking layer 10, the buffer layer 11, the first gate insulating layer 2, the second gate insulating layer 3, the passivation layer 7 in the transition region Q2 and in contact with the base substrate 1. A side away from the aperture region Q2, of the organic encapsulation layer 9 in the first isolation column E1 may cover part of the side edge of the first inorganic encapsulation layer 12 away from the aperture region Q2. A side away from the aperture region Q2, of the second inorganic encapsulation layer 13 in the first isolation column E1 may cover part of the side edge of the organic encapsulation layer 9 away from the aperture region Q2 and is in contact with the first inorganic encapsulation layer 12.

Specifically, as shown in FIGS. 2B and 9, the orthographic projections of the blocking layer 10, the buffer layer 11, the first gate insulating layer 2, the second gate insulating layer 3, and the passivation layer 7 in the first isolation column E1 on the base substrate 1 may be substantially overlapped with each other. The first inorganic encapsulation layer 12 in the first isolation column E1 may wrap the blocking layer 10, the buffer layer 11, the first gate insulating layer 2, the second gate insulating layer 3, and the passivation layer 7 and be in contact with the base substrate 1. The organic encapsulation layer 9 in the first isolation column E1 may cover part of the side edge of the first inorganic encapsulation layer 12, and the second inorganic encapsulation layer 13 in the first isolation column E1 may wrap the organic encapsulation layer 9 and be in contact with the first inorganic encapsulation layer 12.

In specific implementation, in the above display substrate provided by the embodiments of the present disclosure, as shown in FIG. 2A, FIG. 6, and FIG. 7, the side portion (point D) of the first isolation column E1 close to the aperture region Q2 may be provided immediately adjacent to the aperture region Q2, i.e., the first isolation column E1 is immediately adjacent to the boundary position (point D) of the aperture region Q2.

In specific implementation, in the above display substrate provided by the embodiments of the present disclosure, as shown in FIGS. 2B, 8, and 9, the side portion of the first isolation column E1 close to the aperture region Q2 has a first preset distance W1 from the aperture region Q2. By designing the first isolation column E1 not to be immediately adjacent to the boundary position (point D) of the aperture region Q2, i.e., the inorganic film layer and the organic film layer of the first isolation column E1 are inwardly retracted at a position immediately adjacent to the boundary position (point D) of the aperture region Q2, and the inorganic film layer and the organic film layer above the base substrate 1 at the position immediately adjacent to the boundary position (point D) of the aperture Q2 are completely removed. For example, the inorganic film layer and the organic film layer are inwardly retracted by 1 μm to 5 μm along the direction DD′, i.e., the first preset distance W1 is in a range of 1 μm to 5 μm. In comparison to the non-inward retraction design of the inorganic film layer and the organic film layer in FIG. 6 and FIG. 7, the inward retraction design of the inorganic film layer and the organic film layer in the first isolation column E1 can further enhance the stretching deformation capability of the transition region Q11.

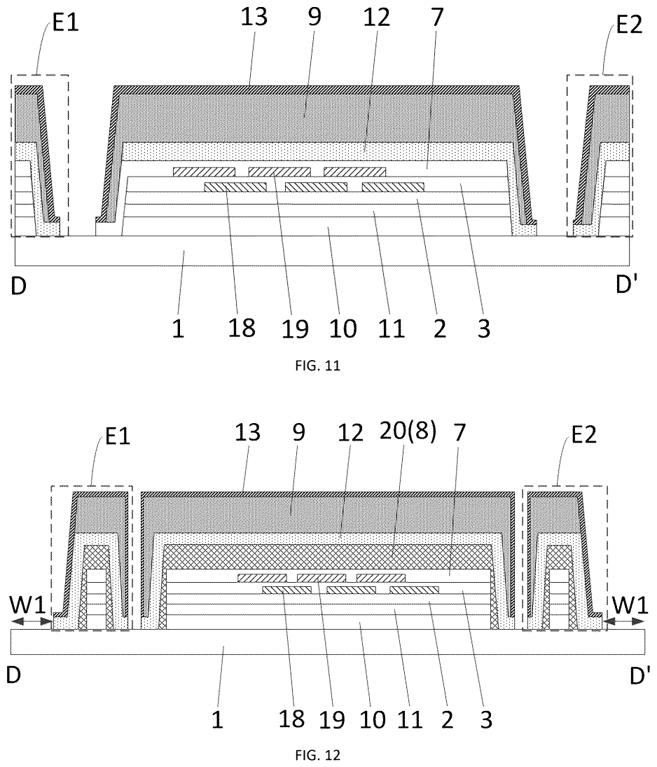

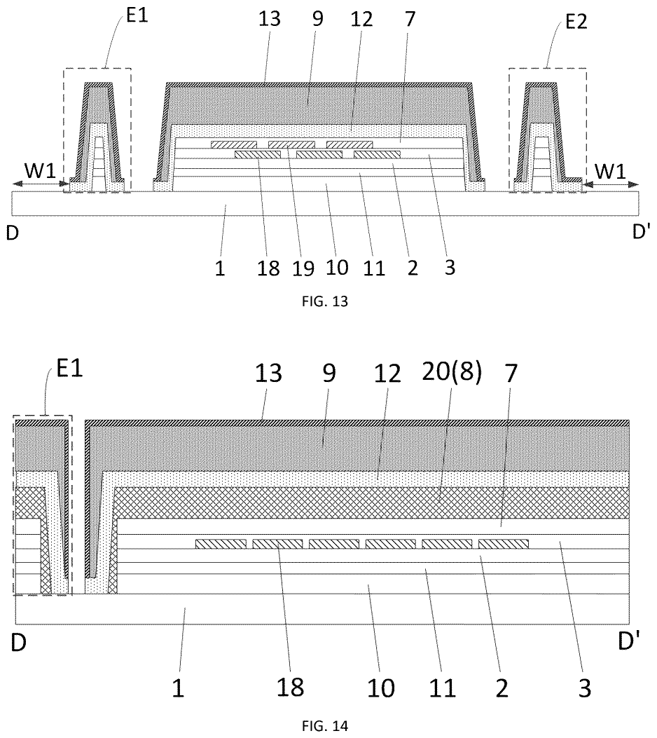

In specific implementation, in the above display substrate provided by the embodiments of the present disclosure, as shown in FIG. 2A, FIG. 2B, and FIG. 10-FIG. 13, FIG. 10 and FIG. 11 each are schematic diagrams of another two sectional structures along the direction DD′ in FIG. 2A, and FIG. 12 and FIG. 13 each are schematic diagrams of another two sectional structures along the direction DD′ in FIG. 2B. A second isolation column E2 is provided in another side portion (e.g., at point D′) of the transition region Q11 close to the aperture region Q2. The second isolation column E2 has the same film layer structure as the first isolation column E1. By designing the second isolation column E2 at another boundary position (e.g., point D′) of the transition region Q11 close to the aperture region Q2, the inorganic film layer and the organic film layer in the second isolation column E2 are physically isolated from the inorganic film layer and the organic film layer in the transition region Q11 away from the aperture region Q2 and the pixel region Q12 along the direction DD′ through a process such as photolithography/etching, so as to avoid that, during the stretching process, the inorganic film layer close to another side of the aperture region Q2 (e.g., point D′) is formed with a crack developing and extending along the direction from D′ to D. The second isolation column E2 has the effect of blocking the extension of the crack of the inorganic film layer, which enhances the stretching deformation capability of the display substrate.

In specific implementation, in the above display substrate provided by the embodiments of the present disclosure, as shown in FIG. 2A, FIG. 2B, and FIG. 10-FIG. 13, the second isolation column E2 and the first isolation column E1 may be symmetrically disposed with respect to the center of the transition region Q11. Of course, it may not be limited to the symmetrical setting of the second isolation column E2 and the first isolation column E1 as shown in FIG. 10-FIG. 13. For example, the first isolation column E1 may be set immediately adjacent to the aperture region Q2, and the second isolation column E2 is done with an inward retraction design. Or, the first isolation column E1 is done with an inward retraction design, and the second isolation column E2 is set immediately adjacent to the aperture region Q2.

It should be noted that the signal line connecting the pixel island regions Q1 adjacent to each other of the display substrate shown in FIG. 6-FIG. 13 adopts a double-layer wiring design, so that the signal line layer at the intermediate position from the point D to the point D′ can be a double-layer wiring design of the first gate metal layer and the second gate metal layer, and the first gate metal layer and the second gate metal layer are separated from each other by the second gate insulating layer 3, which can reduce the width of the transition region Q11 along the direction DD′, so as to meet the requirement of saving the space area of the transition region Q11.

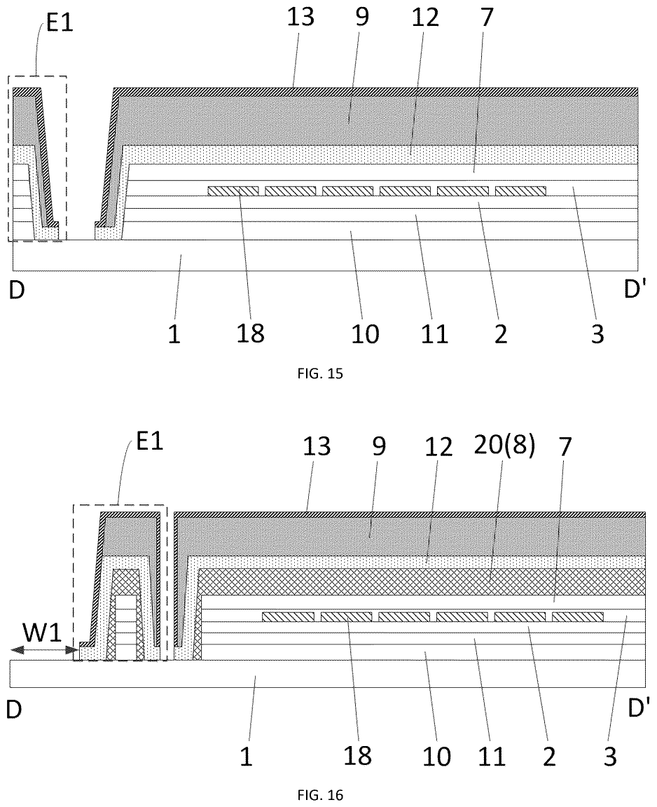

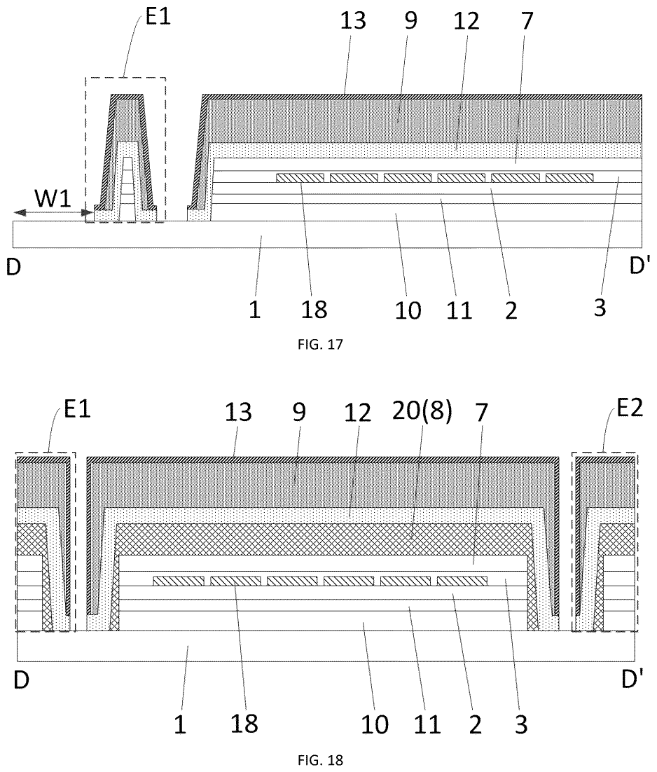

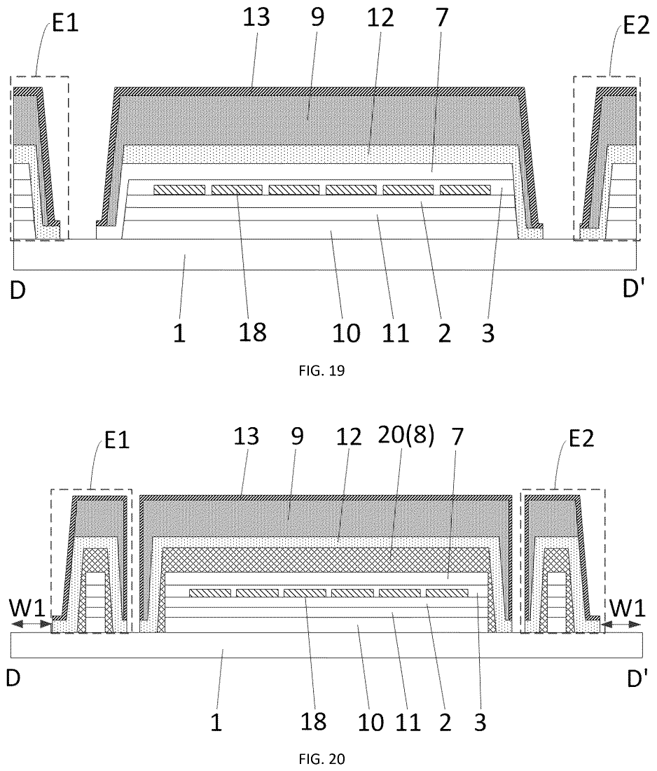

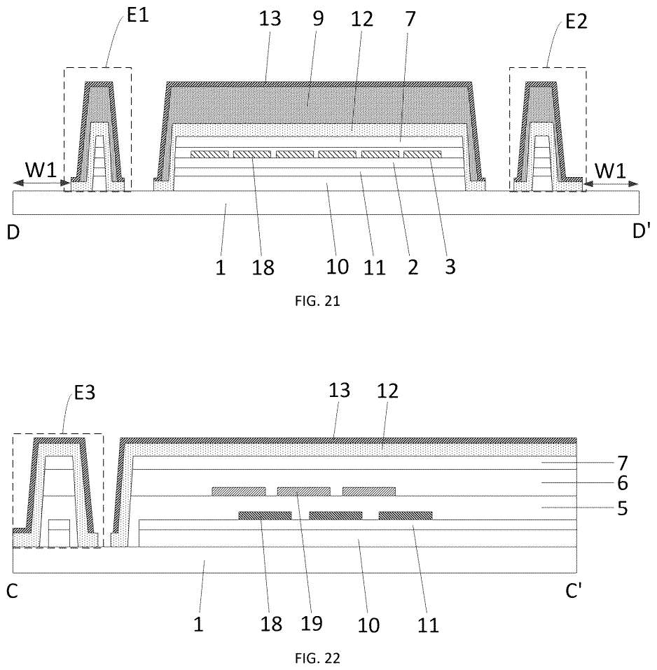

Of course, in specific implementation, the signal line connecting the pixel island regions Q1 that are adjacent to each other in the display substrate can also adopt a single layer wiring design (e.g., routing wirings only using the first gate metal layer or only using the second gate metal layer). In the embodiments of the present disclosure, a single layer wiring in the first gate metal layer is adopted, as shown in FIG. 14-FIG. 21. FIG. 14 is different from FIG. 6 only by adopting a single layer wiring design of the first gate metal layer, and the rest structure in FIG. 14 and FIG. 6 are the same. FIG. 15 is different from FIG. 7 only by adopting a single layer wiring design of the first gate metal layer, and the rest structure in FIG. 15 and FIG. 7 are the same. FIG. 16 is different from FIG. 8 only by adopting a single layer wiring design of the first gate metal layer, and the rest structure in FIG. 16 and FIG. 8 are the same. FIG. 17 is different from FIG. 9 only by adopting a single layer wiring design of the first gate metal layer, and the rest structure in FIG. 17 and FIG. 9 are the same. FIG. 18 is different from FIG. 10 only by adopting a single layer wiring design of the first gate metal layer, and the rest structure in FIG. 18 and FIG. 10 are the same. FIG. 19 is different from FIG. 11 only by adopting a single layer wiring design of the first gate metal layer, and the rest structure in FIG. 19 and FIG. 11 are the same. FIG. 20 is different from FIG. 12 only by adopting a single layer wiring design of the first gate metal layer, and the rest structure in FIG. 20 and FIG. 12 are the same. FIG. 21 is different from FIG. 13 only by adopting a single layer wiring design of the first gate metal layer, and the rest structure in FIG. 21 and FIG. 13 are the same.

In specific implementation, in the above display substrate provided by the embodiments of the present disclosure, as shown in FIG. 6-FIG. 21, the widths of the first isolation column E1 and the second isolation column E2 along the direction DD′ may be in a range of 3 μm to 10 μm.

It should be noted that the patterns of the film layers in the first isolation column E1 at the same position in FIG. 6-FIG. 21 may differ due to the preparation process, and the patterns of the film layers in the second isolation column E2 at the same position may differ due to the preparation process, etc., but as long as the film layers in the first isolation column E1 and the second isolation column E2 are disconnected from the film layers in the transition region, the function of preventing the extension of the crack can be realized. The first isolation column E1 and the second isolation column E2 with various patterns belong to the claimed scope of the present disclosure. In the present disclosure, the specific shapes of the first isolation column E1 and the second isolation column E2 are not limited.

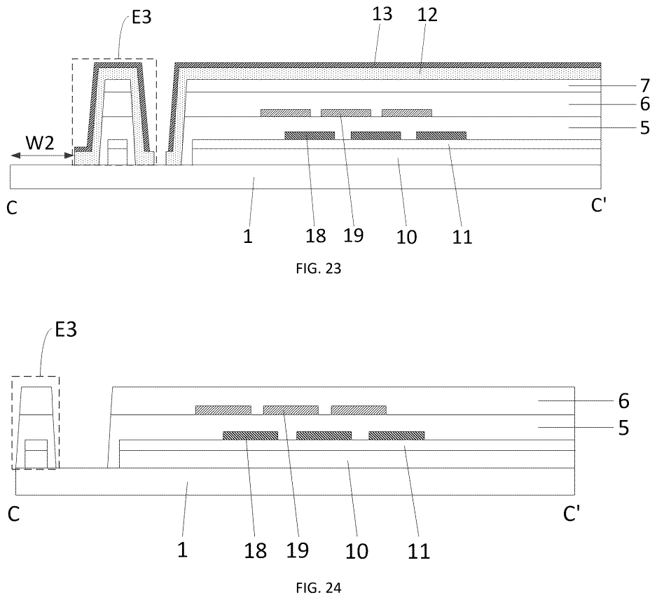

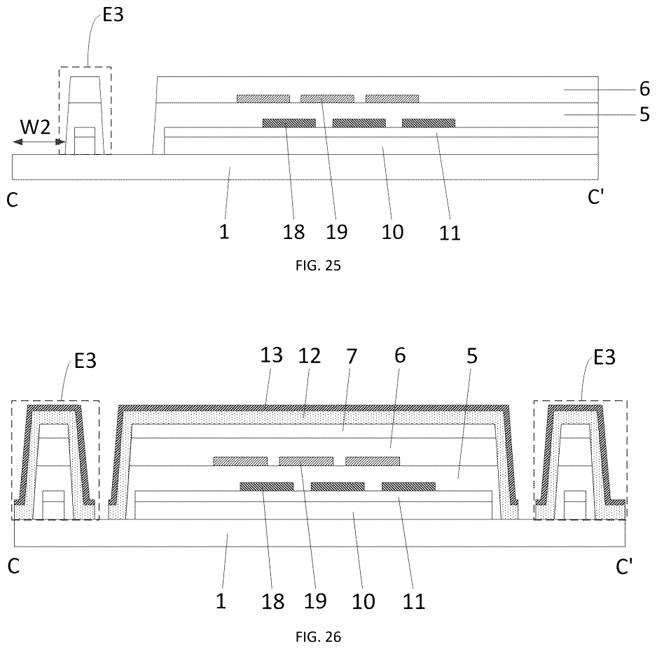

In specific implementation, as shown in FIG. 2A and FIG. 2B, during the stretching process of the display substrate, the inorganic film layer in the connecting bridge region Q3 is prone to crack in addition to that the inorganic film layer at the island-bridge connecting position is prone to crack. During the stretching process, the crack of the inorganic film layer in the connecting bridge region Q3 extends to the inner part of the connecting bridge region Q3 along the boundary of the connecting bridge region Q3 close to the aperture region Q2, that is, the crack extends along the point C to the point C′ (or the point C′ to the point C), which causes the metal wirings in the connecting bridge region to break, resulting in the stretching failure of the display substrate. In order to solve the problem of the crack generated at the inorganic film layer in the connecting bridge region Q3, in the above display substrate provided by the embodiments of the present disclosure, as shown in FIG. 2A, FIG. 2B, FIG. 22-Fig. 25, FIG. 22 and FIG. 24 each are schematic diagrams of two sectional structures along the direction CC′ in FIG. 2A, and FIG. 23 and FIG. 25 each are schematic diagrams of two sectional structures along the direction CC′ in FIG. 2B. The side portion (e.g., point C) of the connecting bridge region Q3 close to the aperture region Q2 is provided with a third isolation column E3 extending along the extension direction of the connecting bridge region Q3. The third isolation column E3 includes at least a part of film layers among the blocking layer 10, the buffer layer 11, the passivation layer 7, the first inorganic encapsulation layer 12, and the second inorganic encapsulation layer 13. By designing the third isolation column E3 including at least a part of the inorganic film layers at the side portion of the connecting bridge region Q3 close to the aperture region Q2 (e.g., at point C), the inorganic film layers in the third isolation column E3 is physically isolated from the inorganic film layers at the connecting bridge region Q3 away from the aperture region Q2 and the pixel region Q12 along the direction CC′ by means of a process such as photolithography/engraving, so as to avoid that, during the stretching process, the inorganic film layers (e.g., at point C) close to the side of the aperture region Q2 is formed with a crack developing and extending along the direction from C to C′. The third isolation column E3 prevents the crack at the side portion of the connecting bridge region Q3 from extending along the connecting bridge region Q3, which reduces the risk of the metal signal line breakage at the connecting bridge region Q3, and further improves the stretching deformation capability of the display substrate.

In specific implementation, in the above display substrate provided by the embodiments of the present disclosure, as shown in FIG. 2A, FIG. 2B, FIG. 22, and FIG. 23, the third isolation column E3 includes the blocking layer 10, the buffer layer 11, the first flat layer 5, the second flat layer 6, the passivation layer 7, the first inorganic encapsulation layer 12, and the second inorganic encapsulation layer 13. In this manner, all the inorganic film layers and organic film layers at the side portion of the connecting bridge region Q3 close to the aperture region Q2 are physically isolated from the inorganic film layers and organic film layers at the side portion of the connecting bridge region Q3 away from the aperture region Q2 by the third isolation column E3, which can completely block the effect of the extension of the crack of the inorganic film layers, thereby further enhancing the stretching deformation capability of the display substrate.

In specific implementation, due to the low fracture elongation of the inorganic film layer, it is easy to crack first and then trigger the signal line to crack, so that the overall stretching performance decreases. Therefore, in the above display substrate provided by the embodiments of the present disclosure, as shown in FIG. 2A, FIG. 2B, FIG. 24, and FIG. 25, the third isolation column E3 may include the blocking layer 10, the buffer layer 11, the first flat layer 5, and the second flat layer 6. In this manner, by removing the passivation layer 7, the first inorganic encapsulation layer 12, and the second inorganic encapsulation layer 13 in the connecting bridge region Q3, the breakage of the signal lines can be avoided to further enhance the stretching performance of the display substrate.

In some embodiments, referring to FIG. 25 and FIG. 16, FIG. 21 shows that the height of the third isolation column E3 may be smaller than the heights of the second isolation column E2 and/or the first isolation column E1. In this manner, by removing the passivation layer 7, the first inorganic encapsulation layer 12, and the second inorganic encapsulation layer 13 in the connecting bridge region Q3, the breakage of the signal lines can be avoided to further enhance the stretching performance of the display substrate.

In some embodiments, as shown with reference to FIG. 16, FIG. 21, and FIG. 25, the second preset distance W2 may be smaller than the first preset distance W1, and such a design is conducive to improving the stretchable performance of the pixel island region Q1.

In specific implementation, in the above display substrate provided by the embodiments of the present disclosure, as shown in FIG. 2A, FIG. 22, and FIG. 24, the side portion of the third isolation column E3 close to the aperture region Q2 is provided immediately adjacent to the aperture region Q2, i.e., the third isolation column E3 is immediately adjacent to the boundary position (point C) of the aperture region Q2, so that the crack brought in the process of biaxial stretching can be blocked by the third isolation column E3 alone.

In specific implementation, in the above display substrate provided by embodiments of the present disclosure, as shown in FIG. 2B, FIG. 23, and FIG. 25, the side portion of the third isolation column E3 close to the aperture region Q2 has a second preset distance W2 from the aperture region Q2. By designing the third isolation column E3 not to be immediately adjacent to the boundary position (point C) of the aperture region Q2, i.e., the inorganic film layer and the organic film layer of the third isolation column E3 are inwardly retracted at a position immediately adjacent to the boundary position (point C) of the aperture region Q2, and the inorganic film layer and the organic film layer above the base substrate 1 at the position immediately adjacent to the boundary position (point C) of the aperture region Q2 are completely removed. For example, the inorganic film layer and organic film layer are inwardly retracted by 1 μm to 3 μm along the direction CC′, i.e., the second preset distance W2 is in a range of 1 μm to 3 μm. In comparison to the non-inward retraction design of the inorganic film layer and the organic film layer in FIG. 22 and FIG. 24, the inward retraction design of the inorganic film layer and the organic film layer in the third isolation column E3 can be further i enhance the stretching deformation capability of the connecting bridge region Q3.

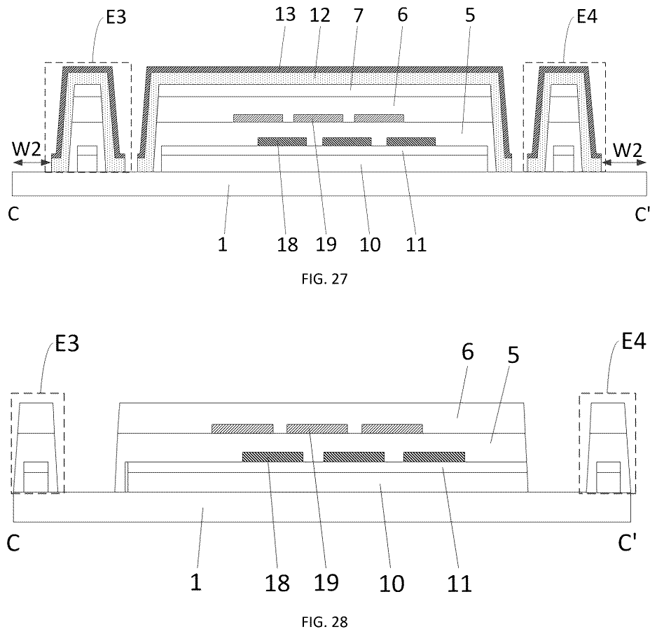

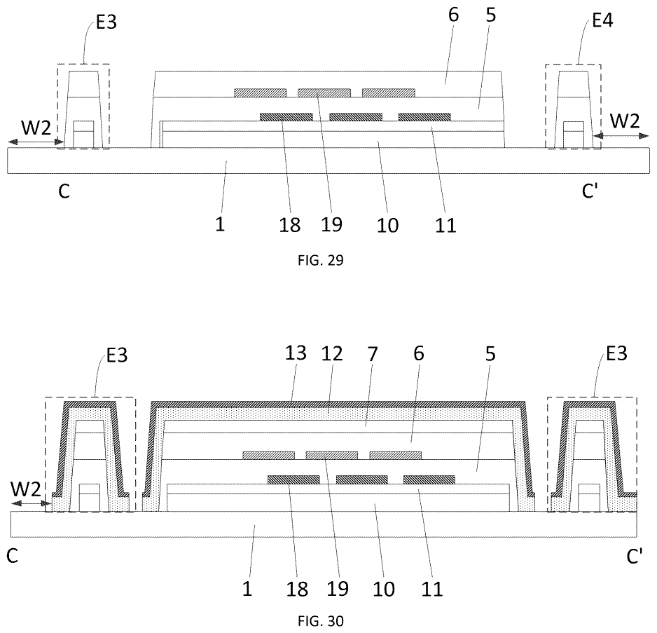

In a specific implementation, in the above display substrate provided by the embodiments of the present disclosure, as shown in FIG. 26-FIG. 29, FIG. 26 and FIG. 28 are schematic diagrams of another two sectional structures along the direction CC′ in FIG. 2A, and FIGS. 27 and 29 are schematic diagrams of another two sectional structures along the direction CC′ in FIG. 2B. Another side portion (e.g., point C′) of the connecting bridge region Q3 close to the aperture region Q2 is provided with a fourth isolation column E4 extending along the extension direction of the connecting bridge region Q3. The fourth isolation column E4 has the same film layer structure as the third isolation column E3. By designing the fourth isolation column E4 at another boundary position (e.g., point C′) of the connecting bridge region Q3 close to the aperture region Q2, the inorganic film layer and the organic film layer in the fourth isolation column E4 are physically isolated from the inorganic film layer and the organic film layer in the connecting bridge region Q3 away from the aperture region Q2 and the pixel region Q12 along the direction CC′ by a process such as photolithography/etching, so as to avoid that, during the stretching process, the inorganic film layer close to another side (e.g., the point C′) of the aperture region Q2 is formed with a crack developing and extending along the direction from C′ to C. The fourth isolation column E4 has the effect of blocking the extension of the crack of the inorganic film layer, which enhances the stretching deformation capability of the display substrate.

In specific implementation, in the above display substrate provided by the embodiments of the present disclosure, as shown in FIG. 26-FIG. 29, the fourth isolation column E4 and the third isolation column E3 are symmetrically disposed with respect to the center of the connecting bridge region Q3. Of course, it may not be limited to the symmetrical setting of the fourth isolation column E4 and the third isolation column E3 as shown in FIG. 26-FIG. 29. For example, as shown in FIG. 30, the third isolation column E3 may be done with an inward retraction design, and the fourth isolation column E4 is set up immediately adjacent to the aperture region Q2. Or, the third isolation column E3 is set up immediately adjacent to the aperture region Q2, and the fourth isolation column E4 is done with an inward retraction design.

It should be noted that the signal line connecting the pixel island regions Q1 adjacent to each other of the display substrate shown in FIG. 26-FIG. 30 adopts a double-layer wiring design, so that the signal line layer at the intermediate position from the point C to the point C′ may be a double-layer wiring design of the first source-drain metal layer and the second source-drain metal layer, and the first source-drain metal layer and the second source-drain metal layer are separated from each other by the second flat layer 5, which can reduce the width of the connecting bridge region Q3 along the direction CC′, and improve the deformation capacity of the connecting bridge region Q3. Of course, the metal wiring in the connecting bridge region Q3 may also be designed with three or more wiring layers.

It should be noted that the shape of the third isolation column E3 in FIG. 22-FIG. 30 may be such that the latter film layer covers the former film layer, may be that the orthographic projections of two adjacent layers approximately flush with each other, or may be both of the above. In addition, the patterns of the film layers in the third isolation column E3 at the same position in FIG. 22-FIG. 30 may differ due to the preparation process, etc., and the patterns of the film layers in the fourth isolation column E4 at the same position may differ due to the preparation process, etc., but as long as the film layers in the third isolation column E3 and the fourth isolation column E4 are disconnected from the corresponding film layers in the connecting bridge region, the function of preventing the extension of cracks can be realized. The third isolation column E3 and the fourth isolation column E4 with various patterns belong to the claimed scope of the present disclosure. In the present disclosure, the specific shapes of the third isolation column E3 and the fourth isolation column E4 are not limited.

In specific implementation, in the above display substrate provided by the embodiments of the present disclosure, as shown in FIG. 2A, FIG. 2B, and FIG. 6-FIG. 30, the third isolation column E3 and the first isolation column E1 are disposed on the same side, and the third isolation column E3 is disconnected from the first isolation column E1; the fourth isolation column E4 and the second isolation column E2 are disposed on the same side, and the fourth isolation column E4 is disconnected from the second isolation column E2.

In specific implementation, in the above display substrate provided by embodiments of the present disclosure, as shown in FIG. 22-FIG. 30, the widths of the third isolation column E3 and the fourth isolation column E4 along the direction CC′ may be in range of 3 μm to 10 μm.

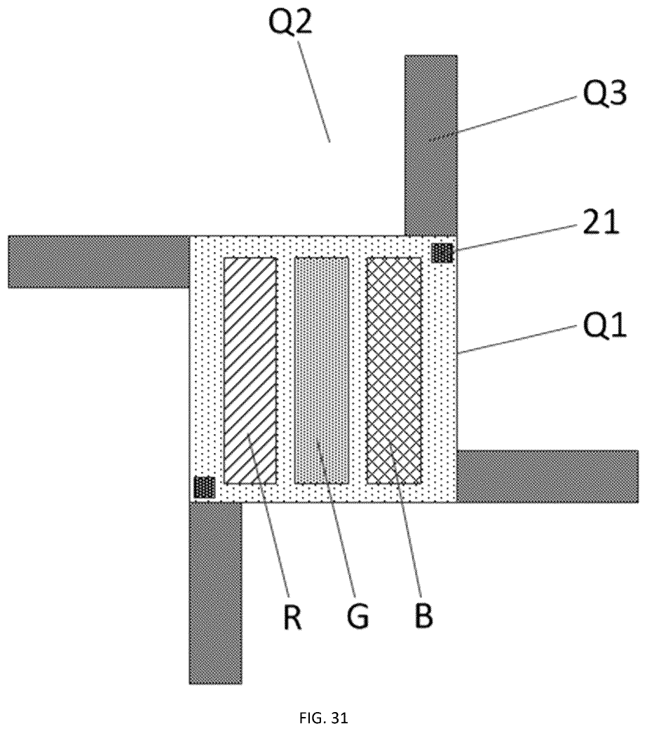

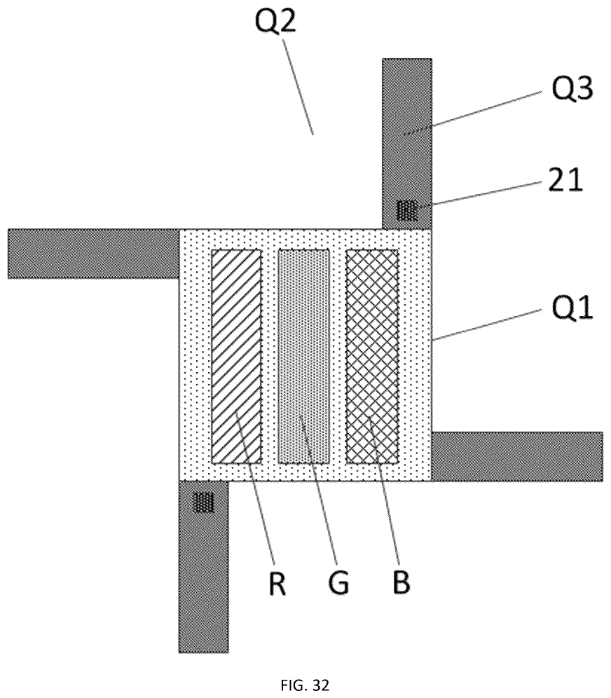

In specific implementation, in the above display substrate provided by the embodiments of the present disclosure, the spacer 21 may be provided at a side portion of the pixel island region Q1 close to the connecting bridge region Q3, as shown in FIG. 31; and the spacer 20 may be provided at a side portion of the connecting bridge region Q3 close to the pixel island region Q1, as shown in FIG. 32. Of course, it is also possible that a portion of the spacer 21 is provided at the side portion of the pixel island region Q1 close to the connecting bridge region Q3, and another portion of the spacer 20 is provided at the side portion of the connecting bridge region Q3 close to the pixel island region Q1. Of course, the spacer 21 may also be provided at any position of the pixel island region Q1 or the connecting bridge region Q3, and the present disclosure is not particularly limited thereto.

In specific implementation, in the above display substrate provided by the embodiments of the present disclosure, as shown in FIGS. 31 and 32, the number of spacers 21 provided in each pixel island region Q1 and the connecting bridge region Q3 connected to the pixel island region Q1 is in a range of 1 to 4.

In specific implementation, in the above display substrate provided by the embodiments of the present disclosure, as shown in FIG. 3-FIG. 5, a second partition groove U2 is provided at a position of the pixel region Q12 close to the transition region Q11, the organic light emitting layer 15 is disconnected at the second partition groove U2, the cathode 16 is disconnected at the second partition groove U2, and the first inorganic encapsulation layer 12 covers the second partition groove U2. Since the organic light emitting layer 15 and the cathode 16 close to the aperture region Q2 are susceptible to intrusion of water and oxygen, the second partition groove U2 can be set to surround all sub-pixels in the pixel island region Q1, or one second partition groove U2 can be set at the periphery of each sub-pixel, so that the second partition groove U2 can disconnect the organic light emitting layer 15 and the cathode 16 close to the aperture region Q2 from the organic light emitting layer 15 and the cathode 16 within the sub-pixels, which can prevent water and oxygen from invading the organic light emitting layer 15 and cathode 16 in the sub-pixels from the aperture region Q2, thereby ensuring the normal display of the display product.

In specific implementation, in the above display substrate provided by embodiments of the present disclosure, as shown in FIGS. 3-5, the second partition groove U2 may penetrate through at least a part of the passivation layer 7 and the second flat layer 6, the side portion of the passivation layer 7 that is close to the second partition groove U2 protrudes out of the side portion of the second flat layer 6 that is close to the second partition groove U2, and the second partition groove U2 is a closed structure around the transition region Q11. In this manner, the portion of the passivation layer 7 protruding with respect to the second flat layer 6 is capable of forming a concave structure with the side surface of the second flat layer 6 and the bottom of the second flat layer 6 close to the base substrate 1. Specifically, the material of the passivation layer 7 is an inorganic material and the material of the second flat layer 6 is an organic material. In this manner, during the process of forming the second partition groove U2, the passivation layer 7 can be etched with an etching substance that has a smaller lateral etching rate for the inorganic material, and the second flat layer 6 can be etched with an etching substance that has a larger lateral etching rate for the organic material, which in turn can form a concave structure on the side walls of the second partition groove U2.

In some embodiments, as shown in FIGS. 3-5, the second partition groove U2 may penetrate at least a part of the passivation layer 7 and the second flat layer 6, and the second partition groove U2 is between the anode 14 and the first partition groove U1; wherein the second partition groove U2 has a width smaller than the width of the first partition groove U1; and the second partition groove U2 has a depth smaller than the depth of the first partition groove U1.

In some embodiments, as shown in FIG. 3-FIG. 5, the boundary of the orthographic projection of the interlayer insulating layer 4 on the base substrate 1 is between the orthographic projection of the second partition groove U2 on the base substrate 1 and the orthographic projection of the first partition groove U1 on the base substrate 1. Such a design is conducive to avoiding the segment difference in the film layers between the second partition groove U2 and the first partition groove U1 from being too large. In some embodiments, as shown in FIG. 3-FIG. 5, at least a part of the cathode 16 and/or the light emitting function layer 15 is retained on the passivation layer 7 between the second partition groove U2 and the first partition groove U1; and at least a part or all of the passivation layer 7 on the first partition groove U1 is free of the cathode 16 or the light emitting function layer 15, so as to form a transition region for the separated cathode 16 or the separated light emitting function layer 15, and to avoid an excessive difference of light in the adjacent regions.

In some embodiments, as shown in FIG. 3-FIG. 5, at least a part of the cathode 16 and/or the light emitting function layer 15 is retained on the passivation layer 7 between the second partition groove U2 and the first partition groove U1. The orthographic projection of a part of the cathode 16 and/or the light emitting function layer 15 on the base substrate 1 is overlapped with both the orthographic projections of the first signal line 18 and the second signal line 19 on the base substrate 1.

It should be noted that the embodiment of the present disclosure is to provide one second partition groove U2 as an example, but of course, in specific implementation, the number of the second partition grooves U2 may be two, three or more, and the plurality of second partition grooves U2 are provided at intervals.

Specifically, the anode may include a transparent conductive film/metal film/transparent conductive film three-layer stacked structure, wherein the material of the transparent conductive film may be indium tin oxide (ITO) or indium zinc oxide (IZO), and the metal film may be a metal film such as Al, Ag, Cu, and the like.

Specifically, the material of the cathode may be any one or more of magnesium (Mg), silver (Ag), aluminum (Al), copper (Cu), or lithium (Li), or an alloy made of any one or more of the above metals.

Specifically, the light emitting device may be an inorganic light emitting diode, an organic light emitting diode (OLED) prepared using organic materials, a micro light emitting diode (Micro LED) or a mini light emitting diode (mini LED). The embodiments of the present disclosure are exemplified by the light emitting device being an organic light emitting diode.

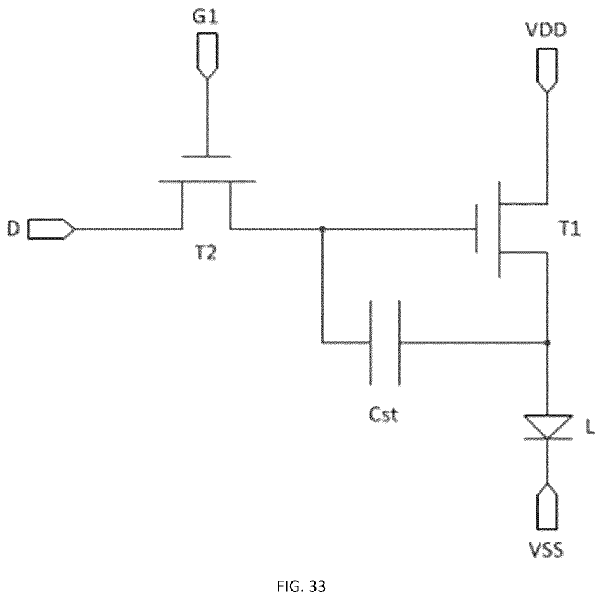

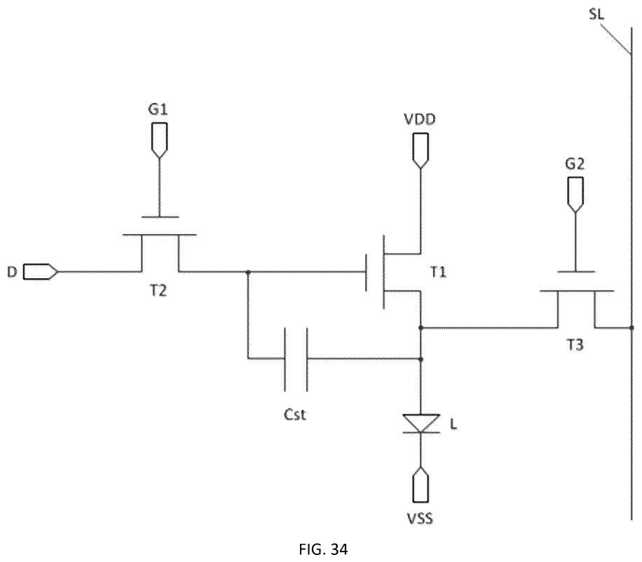

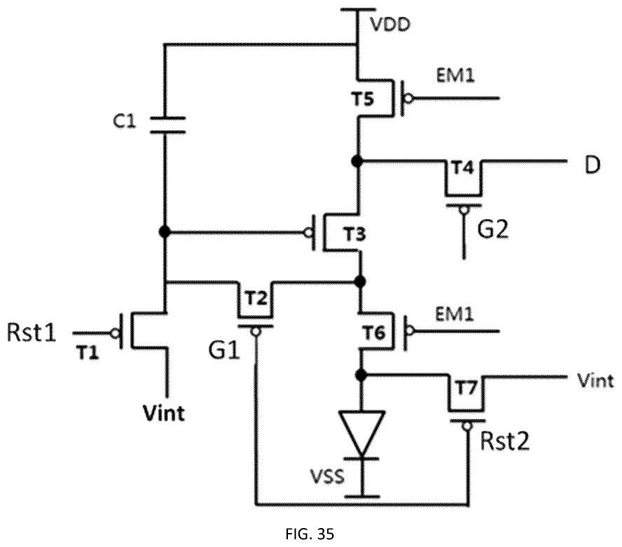

Specifically, the driving circuit may be of various structures, for example, the driving circuit may be a structure including 2 transistors and 1 capacitor (2T1C), as shown in FIG. 33; or the driving circuit may be a structure including 3 transistors and 1 capacitor (3T1C), as shown in FIG. 34; or the driving circuit may be a structure including 7 transistors and 1 capacitor (7T1C), as shown in FIG. 35.

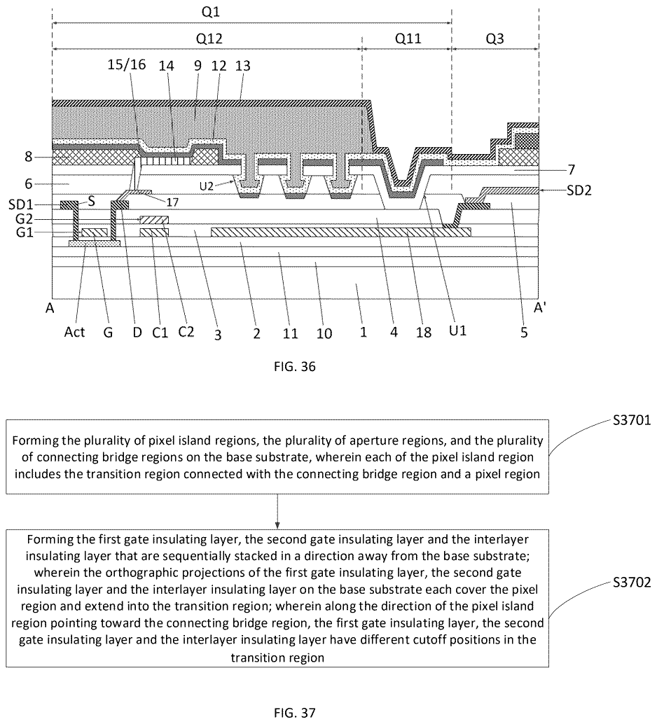

Embodiments of the present disclosure also provide a display substrate, as shown in FIG. 1, FIG. 2A, FIG. 2B, and FIG. 36. FIG. 36 is a schematic diagram of a sectional structure along the direction AA′ in FIGS. 2A and 2B, including a plurality of pixel island regions Q1, a plurality of aperture regions Q2, and a plurality of connecting bridge regions Q3. The pixel island region Q1 includes the transition region Q11 connected to the connecting bridge region Q3, and the pixel region Q12. As shown in FIG. 6-FIG. 21, the first isolation column E1 including at least a part of inorganic film layers is provided on at least one side portion of the transition region Q11 close to the aperture region Q2. The display substrate provided by the embodiment may adopt any of the solutions shown in FIG. 6-FIG. 21, and for specific structural descriptions, refer to the relevant descriptions in FIG. 6-FIG. 21.

Embodiments of the present disclosure also provide a display substrate as shown in FIG. 1, FIG. 2A, FIG. 2B, and FIG. 36. FIG. 36 is a schematic diagram of a sectional structure along the direction AA′ in FIG. 2A and FIG. 2B, including a plurality of pixel island regions Q1, a plurality of aperture regions Q2, and a plurality of connecting bridge regions Q3 as shown in FIG. 22-FIG. 30. The third isolation column E3 that extends along the extension direction of the connecting bridge region Q3 and includes at least a part of the inorganic film layers is provided on at least side portion of the connecting bridge region Q3 close to the aperture region Q2. The display substrate provided by the embodiment may adopt any of the solutions shown in FIG. 22-FIG. 30, and for specific structural descriptions, refer to the relevant descriptions in FIG. 22-FIG. 30.

The embodiment of the present disclosure also provides a display substrate, as shown in FIG. 1, FIG. 2A, FIG. 2B, and FIG. 36. FIG. 36 showing a schematic diagram of a sectional structure along the direction AA′ in FIGS. 2A and 2B, including a plurality of pixel island regions Q1, a plurality of aperture regions Q2, and a plurality of connecting bridge regions Q3. The pixel island region Q1 includes the transition region Q11 connected to the connecting bridge region Q3, and the pixel region Q12.

As shown in FIG. 6-FIG. 30, the first isolation column E1 including at least a part of inorganic film layers is provided on at least one side portion of the transition region Q11 close to the aperture region Q2, and the third isolation column E3 that extends along the extension direction of the connecting bridge region Q3 and includes at least a part of the inorganic film layers is provided at at least side portion of the connecting bridge region Q3 close to the aperture region Q2. The display substrate provided by the embodiment may adopt any of the solutions shown in FIG. 6-FIG. 21 and any of the solutions shown in FIG. 22-FIG. 30, and for specific structural descriptions, refer to the relevant descriptions in FIG. 6-FIG. 30.

Optionally, the present disclosure provides the display substrate shown in FIG. 36 with three second partition grooves U2 provided as an example, and the structure of each of the second partition grooves U2 can be referred to the description shown in the above FIG. 3-FIG. 5.

Optionally, FIG. 36 provided by the present disclosure shows only the first signal line 18, and the first signal line 18 is taken as an example of being jumpered from G1 to SD1, and then being jumpered from SD1 to SD2, and of course, the wiring manner of the signal line can also be referred to as shown in the above FIGS. 3-5.

It should be noted that other film layer structures in FIG. 36 can be seen as described in the above FIG. 3-FIG. 5, and will not be repeated herein.

Optionally, the display substrate provided by the embodiments of the present disclosure is a stretchable display substrate.

Optionally, the display substrate provided by the embodiments of the present disclosure can be used in a display apparatus such as VR (virtual reality), which is of course not limited thereto.

In specific implementation, the above display substrate provided by the present disclosure may also include other functional film layers known to those skilled in the art, which are not described in detail herein.

Based on the same inventive concept, the present disclosure also provides a method for preparing the above display substrate, which is used for preparing the above display substrate provided by the embodiments of the present disclosure. As shown in FIG. 37, the method includes:
S3701, forming the plurality of pixel island regions, the plurality of aperture regions, and the plurality of connecting bridge regions on the base substrate, wherein each of the pixel island region includes the transition region connected with the connecting bridge region and a pixel region; and
S3702, forming the first gate insulating layer, the second gate insulating layer and the interlayer insulating layer that are sequentially stacked in a direction away from the base substrate; wherein the orthographic projections of the first gate insulating layer, the second gate insulating layer and the interlayer insulating layer on the base substrate each cover the pixel region and extend into the transition region; wherein along the direction of the pixel island region pointing toward the connecting bridge region, the first gate insulating layer, the second gate insulating layer and the interlayer insulating layer have different cutoff positions in the transition region.

In the above method for preparing the display substrate provided by the embodiments of the present disclosure, by making the cutoff positions of the first gate insulating layer, the second gate insulating layer, and the interlayer insulating layer in the transition region each different, a design of rigidity gradient variation in the transition region from the pixel island region to the connecting bridge region can be realized, which reduce the risk of a crack at the island-bridge connecting position in the stretching process.

The process for forming each film layer in the present disclosure may include a patterning process and a photolithography process, etc., wherein the patterning process may include treatments such as depositing the film layer, coating the photoresist, mask exposure, developing, etching, stripping the photoresist, etc., and the photolithography process may include treatments such as coating the film layer, mask exposure, developing, etc., wherein the evaporation, deposition, coating, coating, etc., employed are all well-established preparation processes in the related art.

The following is an example of the display substrate shown in FIG. 3, FIG. 6 and FIG. 22, and a detailed description of the process of preparing the display substrate shown in FIG. 3, FIG. 6 and FIG. 22, which may include the following steps.

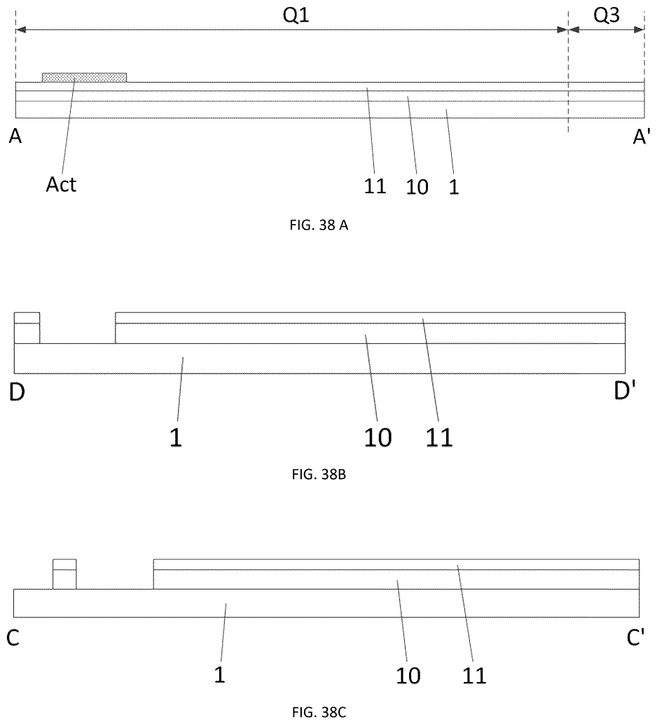

(1) Taking the base substrate 1 including a flexible layer structure as an example, the base substrate 1 is divided into a pixel island region Q1, an aperture region Q2, and a connecting bridge region Q2, the base substrate 1 is formed on the glass substrate 100, a blocking material film layer is deposited on the base substrate 1, a buffer material film layer is formed on the blocking material film layer, the blocking material film layer and the buffer material film layer are patterned by one patterning process to form the blocking layer 10 and the buffer layer 11, portions of the blocking layer 10 and the buffer layer 11 of the first isolation column E1 are formed at the side portion (e.g., point D) of the transition region Q11 close to the aperture region Q2, portions of the blocking layer 10 and the buffer layer 11 of the third isolation column E3 extending along the extension direction of the connecting bridge region Q3 are formed at the side portion (e.g., point C) of the connecting bridge region Q3 close to the aperture region Q2, the orthographic projections of the blocking layer 10 and the buffer layer 11 on the base substrate 1 covers the pixel island region Q1 and the connecting bridge region Q3, and the blocking layer 10 and the buffer layer 11 in the aperture region Q2 are removed. Next, an active layer film (e.g., an amorphous silicon layer) is deposited on the buffer layer 11, and after the amorphous silicon layer is dehydrogenated at a high temperature, an amorphous silicon layer is transformed into polycrystalline silicon using an excimer laser annealing (ELA), and then the polycrystalline silicon layer is patterned by a patterning process to form the active layer Ac which may include partial ion doping, as shown in FIG. 38A, FIG. 38B, and FIG. 38C.

(2) A first gate insulating layer 2 is formed on the active layer Act by a deposition and patterning process, the orthographic projection of the first gate insulating layer 2 on the base substrate 1 covers the pixel region Q12 and the first region Q111 and the second region Q112 in and the transition region Q11, the first gate insulating layer 2 in the third region Q113, the connecting bridge region Q3, and the aperture region Q2 is removed, and the portion of the first gate insulating layer 2 of the first isolation column E1 is formed at a side portion (e.g., point D) of the transition region Q11 close to the aperture region Q2, as shown in FIGS. 39A and 39B.

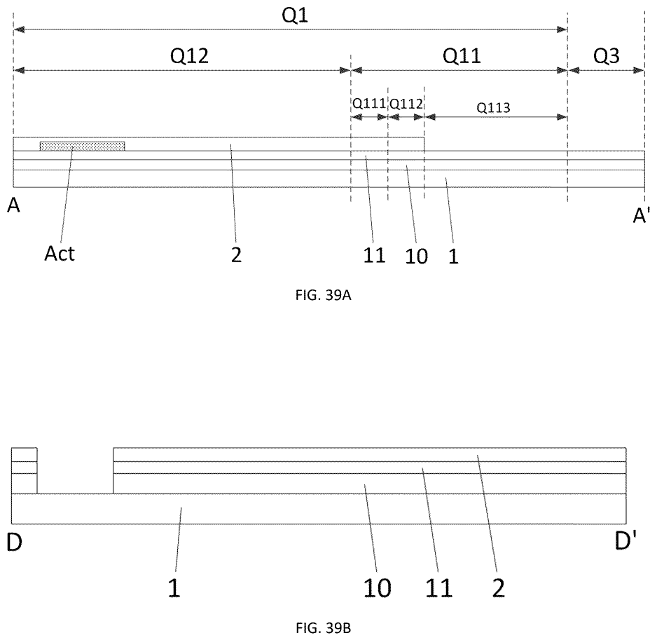

(3) A metal film (the first gate metal layer) is deposited on the first gate insulating layer 2, and the metal film is patterned by a patterning process to form a gate G, a gate line (not shown), a first electrode plate C1, and a portion of the first signal line 18 in the pixel island region Q1 on the first gate insulating layer 2, as shown in FIGS. 40A and 40B.

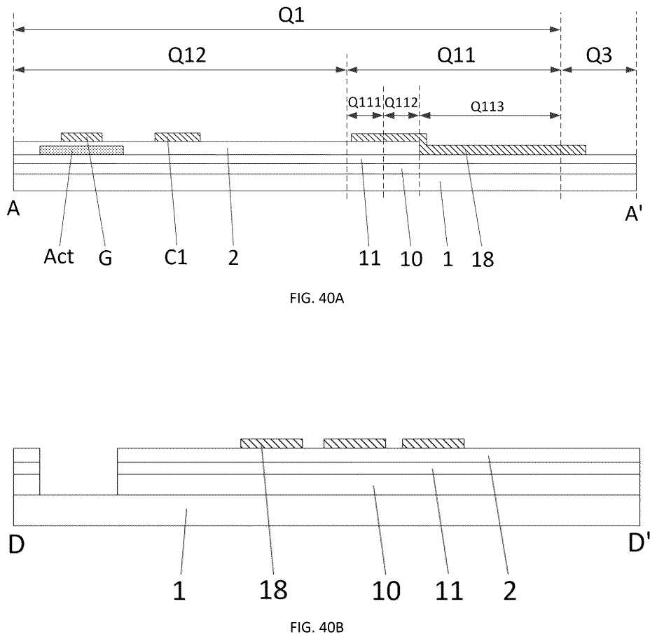

(4) A second gate insulating layer 3 is formed on the gate G by a deposition and patterning process, the orthographic projection of the second gate insulating layer 3 on the base substrate 1 covers the pixel island region Q1, the second gate insulating layer 3 in the connecting bridge region Q3 and the aperture region Q2 is removed, and a portion of the second gate insulating layer 3 in the first isolation column E1 is formed at the side portion (e.g., point D) of the transition region Q11 close to the aperture region Q2, as shown in FIG. 41A and FIG. 41B.

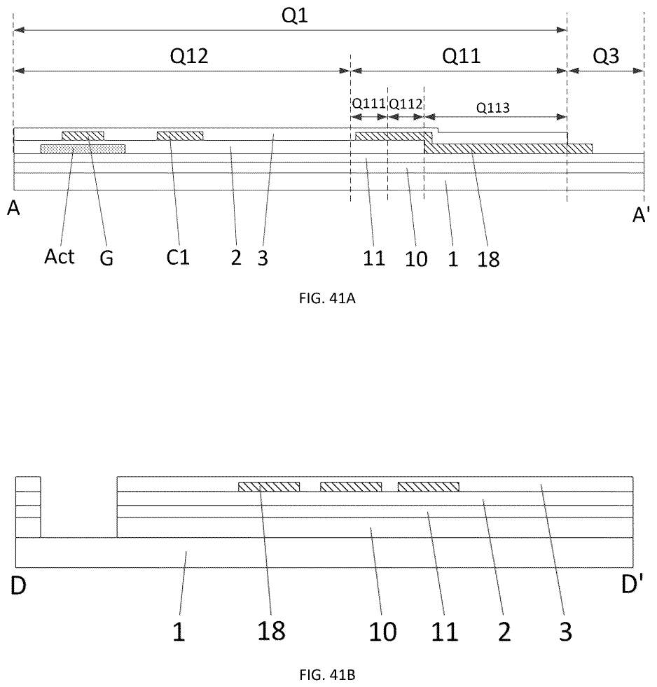

(5) A metal film (the second gate metal layer) is deposited on the second gate insulating layer 3, the metal film is patterned by a patterning process to form a second electrode plate C2 and a portion of the second signal line 19 in the pixel island region Q1 on the second insulating layer 3, and a position of the second electrode plate C2 corresponds to a position of the first electrode plate C1, as shown in FIGS. 42A and 42B.

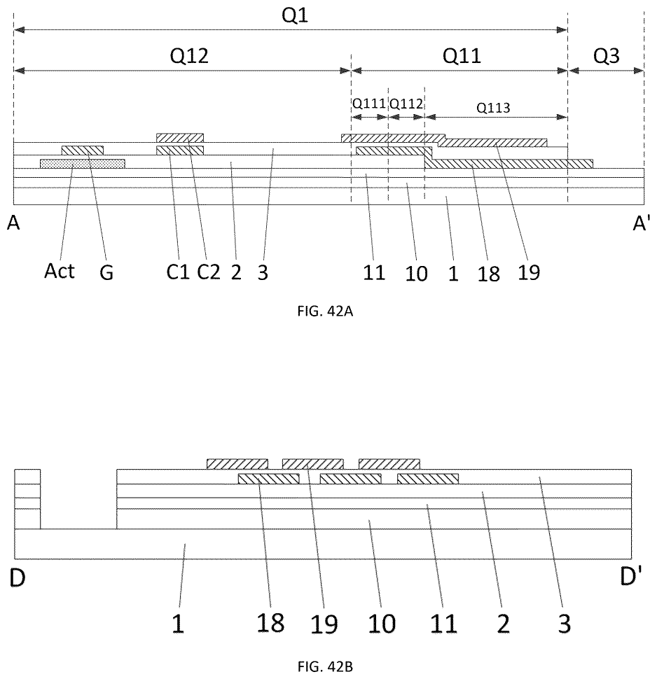

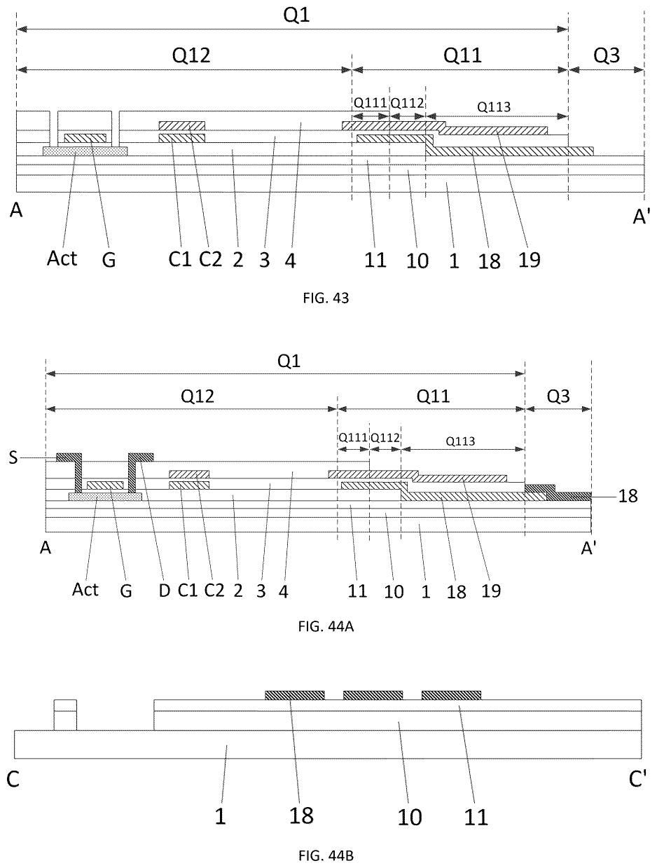

(6) An interlayer insulating layer 4 is formed on the second gate metal layer by a deposition and patterning process, the orthographic projection of the interlayer insulating layer 4 on the base substrate 1 covers the pixel region Q12 and the first region Q111 and the second region Q112 in the transition region Q11, the interlayer insulating layer 4 in the third region Q113, the connecting bridge region Q3, and the aperture region Q2 is removed, and via holes penetrating through the interlayer insulating layer 4, the second gate insulating layer 3, and the first gate insulating layer 2 are provided above the two ends of the active layer Act, as shown in FIG. 43.

(7) A metal film (the first source-drain metal layer) is deposited on the interlayer insulating layer 4, and the metal film is patterned by a patterning process to form a source S, a drain D in the pixel island region Q1 and a portion of the first signal line 18 in the connecting bridge region Q3 on the interlayer insulating layer 4, the portion of the first signal line 18 in the connecting bridge region Q3 is electrically connected to, in the connecting bridge region Q3, the portion of the first signal line 18 in the pixel island region Q1, as shown in FIG. 44A and FIG. 44B.

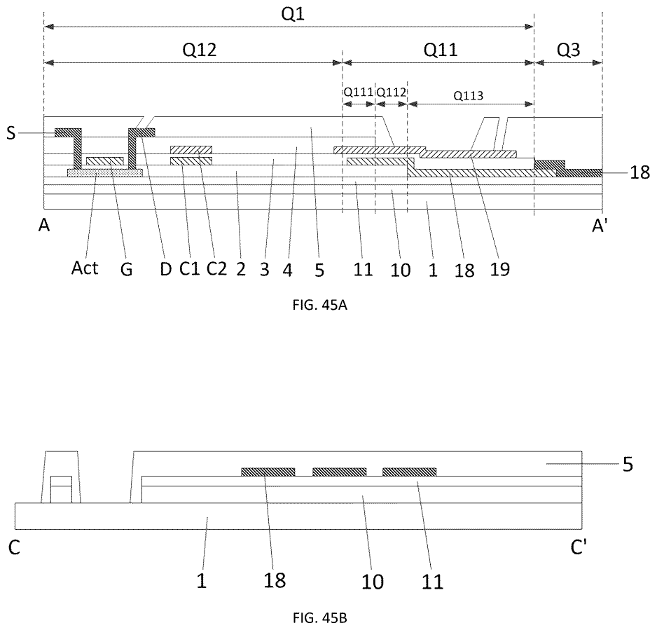

(8) A flat film of organic material is coated on the first source-drain metal layer, and a first flat layer 5 is formed in the pixel island region Q1 by a mask, exposure, and development process, a via hole(s) is provided at a position of the first flat layer 5 corresponding to the drain D, a partition sub-groove of the first partition groove U1 at the first flat layer 5 is provided in the transition region Q11 corresponding to the first flat layer 5, a via hole is provided at a position of the second signal line 19 in the third region Q113 corresponding to the first flat layer 5, the first flat layer 5 in the aperture region Q2 is removed, and a portion of the first flat layer 5 in the third isolation column E3 extending in the extension direction of the connecting bridge region Q3 is formed at the side portion (e.g., at point C) of the connecting bridge region Q3 close to the aperture region Q2, as shown in FIGS. 45A and 45B.

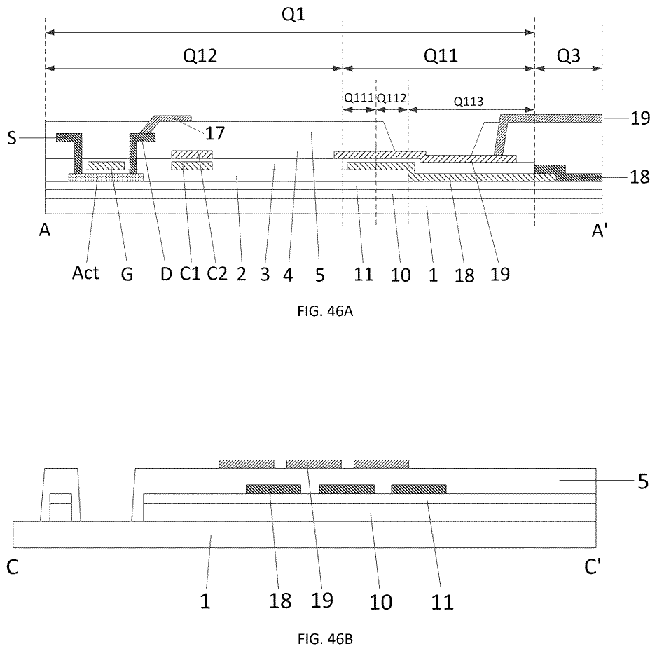

(9) A metal film (the second source-drain metal layer) is deposited on the first flat layer 5, the metal film is patterned by a patterning process to form a lap joint portion 17 on the first flat layer 5 in the pixel island region Q1 as well as a portion of the second signal line 19 in the connecting bridge region Q3, and the portion of the second signal line 19 in the connecting bridge region Q3 is electrically connected to, in the third region Q113, the portion of the second signal line 19 in the pixel island region Q1, as shown in FIG. 46A and FIG. 46B.

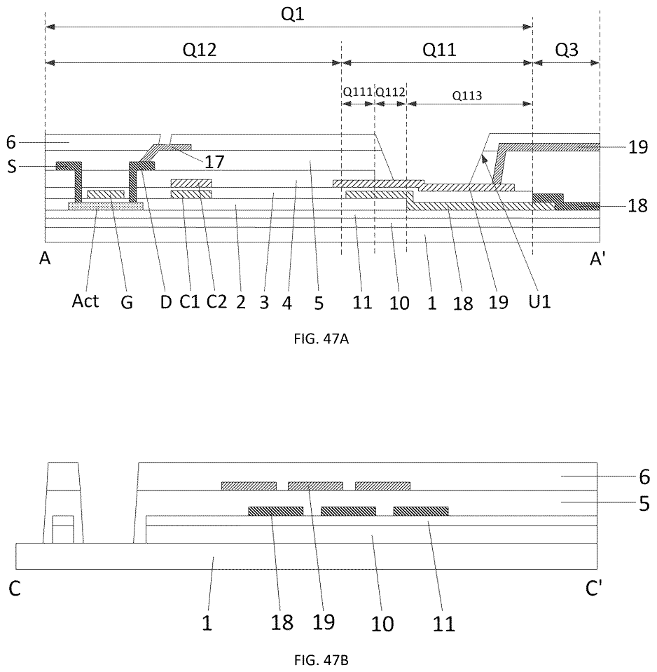

(10) A flat film coated with organic material is formed on the film layer where the lap joint portion 17 is located, a second flat layer 6 is formed by a mask, exposure, and development process, a via hole is provided at a position of the lap joint portion 17 corresponding to the second flat layer 6, a partition sub-groove of the first partition groove U1 in the second flat layer 6 is provided in the transition region Q11 corresponding to the second flat layer 6, the first flat layer 5 in the aperture region Q2 is removed, and a portion of the second flat layer 6 in the third isolation column E3 extending in the extension direction of the connecting bridge region Q3 is formed at the side portion (e.g., at point C) of the connecting bridge region Q3 close to the aperture region Q2, as shown in FIGS. 47A and 47B.

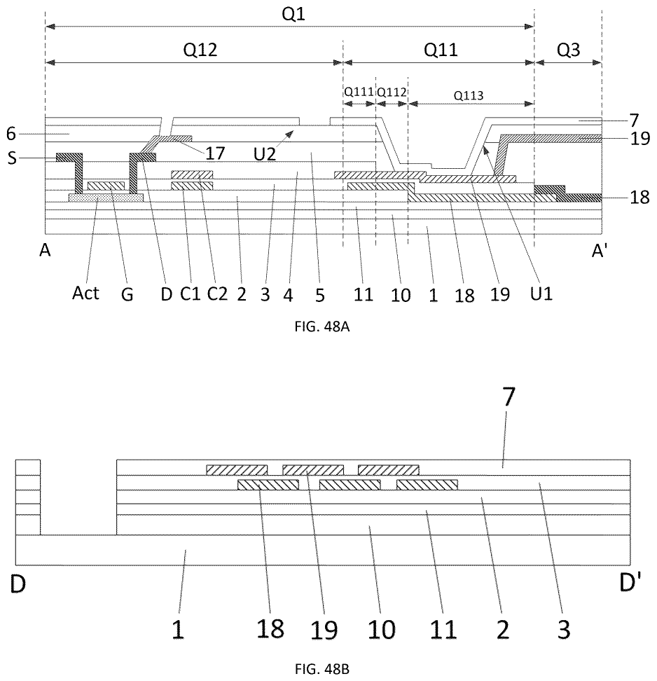

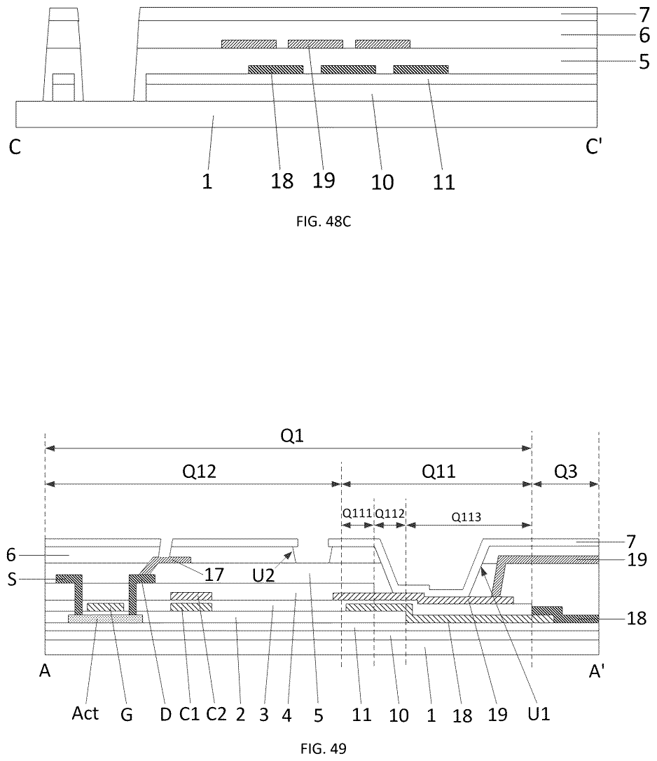

(11) A inorganic insulating material film layer is deposited on the second flat layer 6, the inorganic insulating material film layer is patterned to form the passivation layer 7, a via hole(s) is provided at a position of the passivation layer 7 corresponding to the lap joint portion 17, a partition sub-groove penetrating through the inorganic insulating material film layer is formed at the periphery of all the sub-pixels in the pixel island region Q1, a portion of the passivation layer 7 in the first isolation column E1 is formed at the side portion (e.g., at point D) of the transition region Q11 close to the aperture region Q2, a portion of the passivation layer 7 in the third isolation column E3 extending in the extension direction of the connecting bridge region Q3 is formed at the side portion (e.g., point C) of the connecting bridge region Q3 close to the aperture region Q2, and the passivation layer 7 covers the two sidewalls of the first partition groove U1 and is in direct contact with the portion of the second signal line 19 in the transition region Q11, as shown in FIG. 48A, FIG. 48B, and FIG. 48C.

(12) The second flat layer 6 is exposed and developed using the passivation layer 7 as a mask plate to form a partition sub-groove in the second flat layer 6 below the partition sub-groove in the passivation layer 7, as shown in FIG. 49.

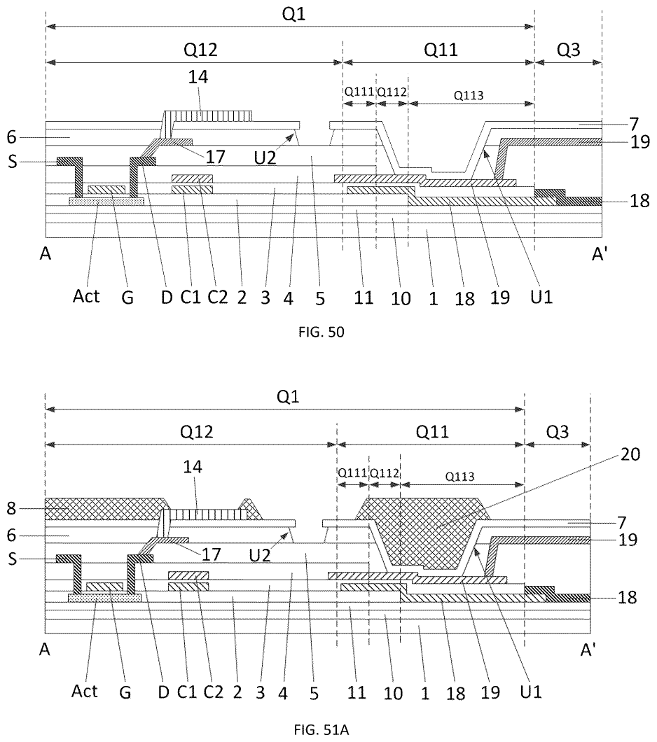

(13) A conductive film is deposited on the passivation layer 7, the conductive film is patterned by a patterning process to form an anode 14, the anode 14 is electrically connected to the lap joint portion 17 through a via hole penetrating through the passivation layer 7 and the second flat layer 6, as shown in FIG. 50.

(14) A pixel-defining film is coated on the anode 14, and a pixel definition layer 8 is formed in the pixel island region Q1 by a mask, exposure, and development process, the pixel definition layer 8 in the pixel island region Q1 is provided with pixel openings, the pixel-defining film within the pixel openings is developed off to expose the surface of the anode 14; and the pixel-defining film corresponding to the position of the aperture region Q2, the position of the connecting bridge region Q3, and the position of the second spacer groove U2 are all developed off, the pixel-defining material is filled in the first partition groove U1 to form the organic compensation layer 20, and a portion of the pixel definition layer 8 in the first isolation column E1 is formed at the side portion (e.g., at point D) of the transition region Q11 close to the aperture region Q2, as shown in FIGS. 51A and 51B.

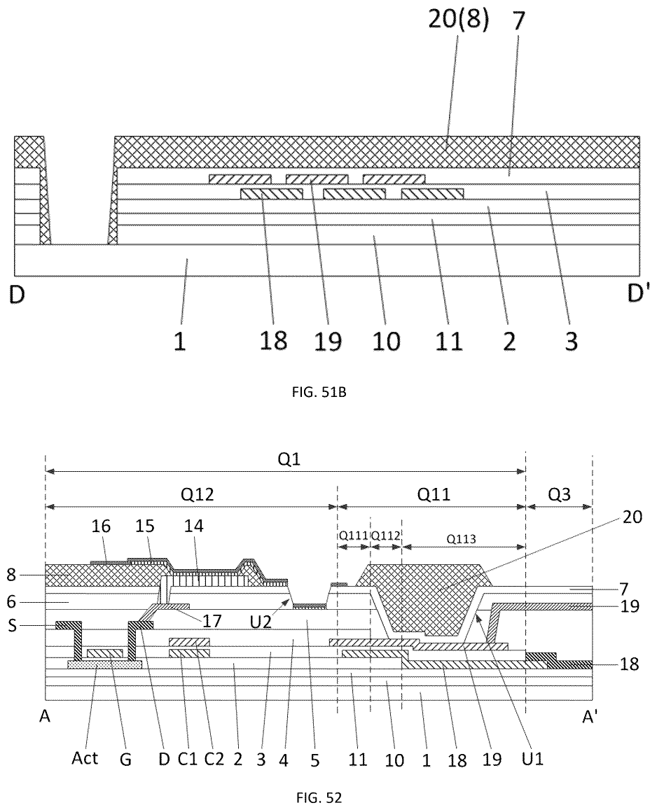

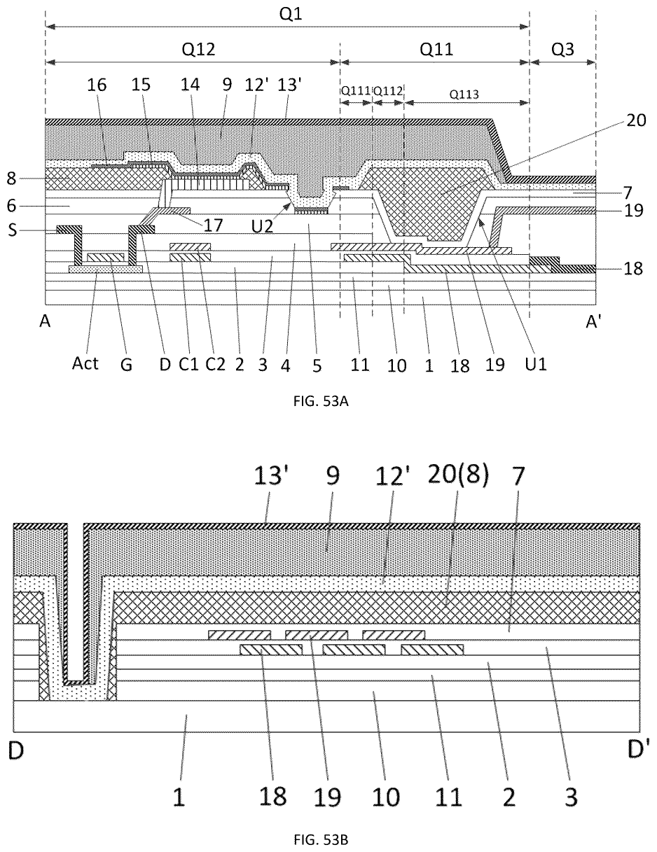

(15) An organic light emitting layer 15 and a cathode 16 are sequentially formed on the pixel definition layer 8, the organic light emitting layer 15 at least covers the pixel openings, and the organic light emitting layer 15 and the cathode 16 are each disconnected at the position of the second isolation groove U2, as shown in FIG. 52.

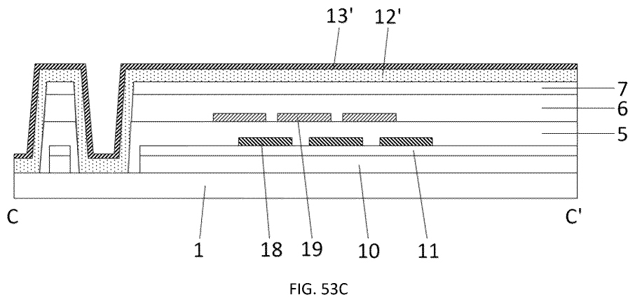

(16) A first inorganic encapsulation film 12′is formed on the cathode 16, an organic encapsulation film is formed on the first inorganic encapsulation film 12′, the organic encapsulation film is subjected to exposure and development, the organic encapsulation layer 9 is formed in the pixel island region Q1, and all organic encapsulation films in the connecting bridge region Q3 and the aperture region Q2 are removed, a portion of the organic encapsulation layer 9 in the first isolation column E1 is formed at the side position (e.g., point D) of the transition region Q11 close to the aperture region Q2, and then a second inorganic encapsulation film 13′ is formed on the organic encapsulation layer 9, as shown in FIG. 53A, FIG. 53B, and FIG. 53C.

(17) The first inorganic encapsulation film 12′ and the second inorganic encapsulation film 13′ are patterned, and the first inorganic encapsulation film 12′ and the second inorganic encapsulation film 13′ corresponding to the aperture region Q2 are removed, the first inorganic encapsulation layer 12 and the second inorganic encapsulation layer 13 are formed in the aperture region Q2, portions of the first inorganic encapsulation layer 12 and the second inorganic encapsulation layer 13 in the first isolation column E1 are formed on the side portion (e.g., at point D) of the transition region Q11 close to the aperture region Q2, portions of the first inorganic encapsulation layer 12 and the second inorganic encapsulation layer 13 in the third isolation column E3 extending along the extension direction of the connecting bridge region Q3 are formed at the side portion (e.g., at point C) of the connecting bridge region Q3 close to the aperture region Q2, and the base substrate 1 is patterned to remove the base substrate 1 in the aperture region Q2 by using the first inorganic encapsulation layer 12 and the second inorganic encapsulation layer 13 as a mask plate, as shown in FIG. 3, FIG. 6, and FIG. 22.

Finally, a protective film is applied to the second inorganic encapsulation layer 13, then the glass substrate 100 is peeled off by a laser peeling process, and then the protective film is removed, that is, the stretchable display substrate is formed.

It should be noted that the embodiments of the present disclosure are illustrated as an example of the method for preparing the display substrate shown in FIG. 3. The method for preparing the display substrate shown in FIG. 4 is similar to the method for preparing the display substrate shown in FIG. 3, with the difference being that in the above step (14), the first partition groove U1 is filled with spacer material to form the organic compensator layer 20. The method for preparing the display substrate shown in FIG. 5 is similar to the method for preparing the display substrate shown in FIG. 3, with the difference being that the organic compensation layer 20 is filled when forming the organic encapsulation layer 9 in the above step (16).

Based on the same inventive concept, the present disclosure also provides a display apparatus including any of the above display substrates provided in the present disclosure. The display apparatus may be: a cell phone, a tablet computer, a television, a monitor, a laptop computer, a digital photo frame, a navigator, and any other product or component having a display function. The implementation of the display apparatus can be seen in the above embodiments of the display substrate, and the repetition will not be repeated.

The above display apparatus may be an organic light emitting diode (OELD) display apparatus, or an active matrix organic light emitting diode (AM-OLED) display apparatus, or a quantum dot light emitting diode (QELD) display apparatus.

Embodiments of the present disclosure provide a display substrate, a method for preparing the same, and a display apparatus, in which the cutoff positions of the first gate insulating layer, the second gate insulating layer, and the interlayer insulating layer are set to be different in the transition region, so that a design of rigidity gradient variation in the transition region from the pixel island region to the connecting bridge region can be realized, which reduce the risk of a crack at the island-bridge connecting position in the stretching process.

Although preferred embodiments of the present disclosure have been described, additional changes and modifications may be made to these embodiments once the basic inventive concepts are known to one of skill in the art. Therefore, the appended claims are intended to be construed to include the preferred embodiments as well as all changes and modifications that fall within the scope of the present disclosure.

Obviously, a person skilled in the art can make various modifications and variations to the presently disclosed embodiments without departing from the spirit and scope of the presently disclosed embodiments. Thus, if such modifications and variations of the presently disclosed embodiments fall within the scope of the presently disclosed claims and their technical equivalents, the present disclosure is intended to include such modifications and variations.

1-32. (canceled)

33. A display substrate, comprising: a plurality of pixel island regions, a plurality of aperture regions, and a plurality of connecting bridge regions, wherein each of the pixel island regions comprises a transition region connected to a connecting bridge region and a pixel region; and
the display substrate comprises: a base substrate, and a first gate insulating layer, a second gate insulating layer and an interlayer insulating layer that are sequentially stacked in a direction away from the base substrate; wherein orthographic projections of the first gate insulating layer, the second gate insulating layer and the interlayer insulating layer on the base substrate each cover the pixel region and extend into the transition region; and along a direction of the pixel island region pointing toward the connecting bridge region, the first gate insulating layer, the second gate insulating layer and the interlayer insulating layer comprise different cutoff positions in the transition region.

34. The display substrate according to claim 33, wherein the cutoff position of the second gate insulating layer in the transition region is adjacent to the connecting bridge region, and the cutoff position of the first gate insulating layer in the transition region and the cutoff position of the interlayer insulating layer in the transition region are both away from the connecting bridge region.

35. The display substrate according to claim 34, wherein the transition region is divided into a first region, a second region, and a third region along a direction of the pixel island region pointing toward the connecting bridge region, wherein the orthographic projection of the second gate insulating layer on the base substrate covers an orthographic projection of the transition region on the base substrate, and the orthographic projection of the first gate insulating layer on the base substrate covers orthographic projections of the first region and the second region on the base substrate, the orthographic projection of the interlayer insulating layer on the base substrate covers the orthographic projection of the first region on the base substrate.

36. The display substrate according to claim 33, further comprising: a first flat layer, a second flat layer, and a passivation layer sequentially stacked on one side away from the base substrate, of the interlayer insulating layer, wherein orthographic projections of the first flat layer and the second flat layer on the base substrate each cover the pixel island region and the connecting bridge region, and an orthographic projection of the passivation layer on the base substrate at least covers the pixel island region; wherein
the first flat layer and the second flat layer comprise a first partition groove penetrating through the first flat layer and the second flat layer in the transition region, the passivation layer covers the first partition groove, and the first partition groove above the passivation layer is filled with an organic compensation layer, so that an overall thickness of the transition region coincides with an overall thickness of the pixel region of the pixel island region.

37. The display substrate according to claim 36, further comprising: a pixel definition layer, a spacer, and an organic encapsulation layer sequentially stacked on one side away from the base substrate, of the passivation layer, wherein the organic compensation layer is of a material same as a material of one of the pixel definition layer, the spacer, or the organic encapsulation layer.

38. The display substrate according to claim 37, further comprising: a blocking layer between the base substrate and the first gate insulating layer, a buffer layer between the blocking layer and the first gate insulating layer, a first inorganic encapsulation layer between the spacer and the organic encapsulation layer, and a second inorganic encapsulation layer on one side away from the base substrate, of the organic encapsulation layer; and
a first isolation column is provided in a side portion close to a aperture region, of the transition region, wherein the first isolation column comprises at least a part of the blocking layer, the buffer layer, the first gate insulating layer, the second gate insulating layer, the passivation layer, the first inorganic encapsulation layer, or the second inorganic encapsulation layer.

39. The display substrate according to claim 38, wherein the first isolation column comprises the blocking layer, the buffer layer, the first gate insulating layer, the second gate insulating layer, the passivation layer, the organic compensation layer, the first inorganic encapsulation layer, the organic encapsulation layer, and the second inorganic encapsulation layer, or the first isolation column comprises the blocking layer, the buffer layer, the first gate insulating layer, the second gate insulating layer, the passivation layer, the first inorganic encapsulation layer, the organic encapsulation layer, and the second inorganic encapsulation layer.

40. The display substrate according to claim 39, wherein the side portion close to the aperture region, of the first isolation column is immediately adjacent to the aperture region.

41. The display substrate according to claim 39, wherein the side portion close to the aperture region, of the first isolation column is provided with a first preset distance from the aperture region.

42. The display substrate according to claim 41, wherein the first preset distance is in a range of 1 μm to 5 μm.

43. The display substrate according to claim 38, wherein a second isolation column is provided in another side portion close to the aperture region, of the transition region, wherein the second isolation column comprises a film layer structure same as a film layer structure of the first isolation column.

44. The display substrate according to claim 43, wherein the second isolation column and the first isolation column are provided symmetrically with respect to a center of the transition region.

45. The display substrate according to claim 38, wherein a third isolation column extending in an extension direction of the connecting bridge region is provided in a side portion close to the aperture region, of the connecting bridge region, wherein the third isolation column comprises at least a part of the blocking layer, the buffer layer, the passivation layer, the first inorganic encapsulation layer, or the second inorganic encapsulation layer.

46. The display substrate according to claim 45, wherein the third isolation column comprises the blocking layer, the buffer layer, the first flat layer, the second flat layer, the passivation layer, the first inorganic encapsulation layer, and the second inorganic encapsulation layer, or the third isolation column comprises the blocking layer, the buffer layer, the first flat layer and the second flat layer.

47. The display substrate according to claim 46, wherein a side portion close to the aperture region, of the third isolation column is immediately adjacent to the aperture region.

48. The display substrate according to claim 46, wherein a side portion close to the aperture region, of the third isolation column is provided with a second preset distance from the aperture region.

49. The display substrate according to claim 48, wherein the second preset distance is in a range of 1 μm to 3 μm.

50. The display substrate according to claim 45, wherein a fourth isolation column extending in the extension direction of the connecting bridge region is provided in another side portion close to the aperture region, of the connecting bridge region, wherein the fourth isolation column comprise a film layer structure same as a film layer structure of the third isolation column.

51. The display substrate according to claim 50, wherein the fourth isolation column and the third isolation column are provided symmetrically with respect to a center of the connecting bridge region.

52. The display substrate according to claim 45, wherein the third isolation column and the first isolation column are provided on the same side and the third isolation column and the first isolation column are disconnected from each other.

53. The display substrate according to claim 37, wherein the spacer is provided in a side portion close to the aperture region, of the pixel island region, and/or the spacer is provided in a side portion close to the pixel island region, of the connecting bridge region.

54. The display substrate according to claim 53, wherein a number of the spacers provided in each pixel island region and the connecting bridge region connecting to the pixel island region is in a range of 1 to 4.

55. The display substrate according to claim 38, further comprising: an anode between the passivation layer and the pixel definition layer, an organic light emitting layer between the pixel definition layer and the first inorganic encapsulation layer, and a cathode between the organic light emitting layer and the first inorganic encapsulation layer; and
a second partition groove is provided at a position of the pixel region close into the transition region, wherein the organic light emitting layer is disconnected at the second partition groove, the cathode is disconnected at the second partition groove, and the first inorganic encapsulation layer covers the second partition groove.

56. The display substrate according to claim 55, wherein the second partition groove penetrates through at least a part of the passivation layer and the second flat layer, a side portion close to the second partition groove, of the passivation layer protrudes out of a side portion close to the second partition groove, of the second flat layer, and the second partition groove is a closed structure around the transition region.

57. The display substrate according to claim 36, further comprising: a first gate metal layer between the first gate insulating layer and the second gate insulating layer, a second gate metal layer between the second gate insulating layer and the interlayer insulating layer, a first source-drain metal layer between the interlayer insulating layer and the first flat layer, and a second source-drain metal layer between the first flat layer and the second flat layer; and
each of the pixel island regions comprises at least one sub-pixel, and the display substrate further comprises a plurality of signal lines, which are arranged in the connecting bridge region, extend into the pixel island region, and are electrically connected to the at least one sub-pixel; wherein
the plurality of signal lines comprise a first signal line and a second signal line stacked; wherein a portion of the first signal line in the pixel island region is provided in the first gate metal layer, a portion of the first signal line in the connecting bridge region is provided in the first source-drain metal layer, a portion of the second signal line in the pixel island region is provided in the second gate metal layer, and a portion of the second signal line in the connecting bridge region is provided in the second source-drain metal layer.

58. A display substrate, comprising: a plurality of pixel island regions, a plurality of aperture regions, and a plurality of connecting bridge regions, the display substrate further comprises one of followings:
each of the pixel island regions comprises a transition region connected to a connecting bridge region and a pixel region; and a first isolation column comprising at least a part of inorganic film layers is provided in at least one side portion close to an aperture region, of a transition region;
a third isolation column comprising at least a part of inorganic film layers extending in an extension direction of the connecting bridge region is provided in a connecting bridge region close to an aperture region;
or
each of the pixel island regions comprises a transition region connected to a connecting bridge region and a pixel region; wherein a first isolation column comprising at least a part of inorganic film layers is provided in at least one side portion of a transition region close to an aperture region, and a third isolation column comprising at least a part of inorganic film layers extending in an extension direction of the connecting bridge region is provided in a connecting bridge region close to an aperture region.

59. A display apparatus, comprising the display substrate according to claim 33.

60. A method for preparing the display substrate according to claim 33, comprising:
forming the plurality of pixel island regions, the plurality of aperture regions, and the plurality of connecting bridge regions on the base substrate, wherein each of the pixel island region comprises the transition region connected with the connecting bridge region and a pixel region; and
forming the first gate insulating layer, the second gate insulating layer and the interlayer insulating layer that are sequentially stacked in a direction away from the base substrate; wherein the orthographic projections of the first gate insulating layer, the second gate insulating layer and the interlayer insulating layer on the base substrate each cover the pixel region and extend into the transition region; wherein along the direction of the pixel island region pointing toward the connecting bridge region, the first gate insulating layer, the second gate insulating layer and the interlayer insulating layer comprise different cutoff positions in the transition region.
